(19) United States
(12) Patent Application Publication
(10) Pub. No.: US 2026/0004013 A1
(43) Pub. Date: Jan. 1, 2026

(54) UPDATING BASE DESIGNS IN INDUSTRIAL DESIGN APPLICATIONS USING GENERATIVE ARTIFICIAL INTELLIGENCE

(71) Applicant: Rockwell Automation Technologies, Inc., Mayfield Heights, OH (US)

(72) Inventors: Brian C. Frank, Cedarburg, WI (US); Gerald W. Renderman, West Bend, WI (US); John P. Mason, Sussex, WI (US); Matthew S. Hill, Kitchener (CA); Chao G. Moua, Mequon, WI (US)

(21) Appl. No.: 18/754,950

(22) Filed: Jun. 26, 2024

(51) Int. Cl. G06F 30/17; G06F 30/27

(52) U.S. Cl. CPC G06F 30/17; G06F 30/27

(57) ABSTRACT

The present disclosure describes systems and methods for updating industrial designs in a library of industrial designs. Embodiments include leveraging a Generative Artificial Intelligence (GAI) model to update the designs. The GAI model is trained to recognize common selections of configuration options among users of the industrial design application. The disclosure describes generating prompts requesting the GAI model to update the industrial designs based on the common selections of the users. The disclosure also describes leveraging the GAI model to update option packs within industrial designs, according to some embodiments.

### RELATED APPLICATIONS

This U.S. Patent Application is related to co-pending U.S. Patent Application titled “PROFILE-BASED PROMPT ENGINEERING FOR USER-SPECIFIC INDUSTRIAL AUTOMATION PROJECT CUSTOMIZATION,” Attorney Docket Number 2024P-025-US, filed concurrently, the contents of which are incorporated herein in their entirety for all purposes.

This U.S. Patent Application is related to co-pending U.S. Patent Application titled “COMMON CONFIGURATION VALIDATION IN INDUSTRIAL DESIGN APPLICATIONS USING GENERATIVE ARTIFICIAL INTELLIGENCE,” Attorney Docket Number 2024P-026-US filed concurrently, the contents of which are incorporated herein in their entirety for all purposes.

This U.S. Patent Application is related to co-pending U.S. Patent Application titled “INDUSTRIAL BASE DESIGN GENERATION USING GENERATIVE ARTIFICIAL INTELLIGENCE,” Attorney Docket Number 2024P-028-US, filed concurrently, the contents of which are incorporated herein in their entirety for all purposes.

### TECHNICAL FIELD

The disclosure generally relates generally to utilizing Generative Artificial Intelligence (GAI) models, such as a Large Language Models (LLMs) or Multi-Modal Models (MMMs), to update a base design repository, and more specifically to update base designs of industrial units based on common configuration selections across a variety of users.

### BACKGROUND

In preparation for building, updating, or modifying industrial systems in a factory, an engineer may use an industrial design application to plan details, including selecting components (e.g., machines, controllers, cabinets, and the like), selecting configuration settings of the components, and designing layouts of the system. Once configured, the engineer can submit the design for quoting using the industrial design application.

Industrial design applications store designs for industrial units in a database of designs. The industrial design application may select designs from the database and provide them to engineers as initial designs in the industrial automation project. Since industrial standards (e.g., common configuration selections made by engineers) change over time, the industrial units stored in the database may become outdated. For example, a design configuration that was once popular may become unpopular in a certain area due to a change in local regulations. As a result, industrial design applications may provide designs to users that are outdated, reducing the quality of initial designs provided to users. Maintaining a database of all relevant common preferences to update industrial designs is resource-intensive, cumbersome, and may be cost prohibitive.

### SUMMARY

This disclosure describes leveraging a GAI model to update generic base designs in a base design repository. The base design repository is a library of generic base designs provided to users of an industrial design application. Upon receiving generic base designs, users may customize the design, for example by selecting various options within the option packs of the generic base designs. Using the GAI model to update the generic base design keeps the base design, including option packs, up to date with common selections made in various industries and locations.

One example of a computer-implemented method for updating a generic base design performed according to some embodiments includes determining that a trigger for updating the generic base design of an industrial unit has been satisfied. The generic base design is one of a plurality of generic base designs stored in a base design repository. The generic base design includes metadata defining the industrial unit. The method further includes generating, in response to determining that the trigger has been satisfied, a prompt to elicit a response from a Generative Artificial Intelligence (GAI) model. The GAI model is trained on data including previous industrial design submissions from a plurality of users of an industrial design application. The prompt includes: the metadata of the generic base design and a request to update the generic base design based on the previous industrial design submissions. The method further includes submitting the prompt to the GAI model. The method further includes receiving, from the GAI model in response to the prompt. The updated base design includes one or more differences from the generic base design. The differences are representative of previous selections made in the previous industrial design submissions from the plurality of users of the industrial design application.

In some embodiments, the method further includes receiving, from an administrator of the industrial design application, a request to update the generic base design. The method further includes determining that a pre-determined time-period has elapsed since a last update of the generic base design. The method further includes determining that the generic base design has been selected for initial designs provided to users above a threshold number of times.

In some embodiments the method further includes sending to an administrator of the industrial design application, in response to receiving the updated generic base design, a request to review the updated base design. The method further includes receiving, from the administrator in response to the request, an approval of the updated base design.

In some embodiments, the method further includes replacing, in response to receiving the approval, the generic base design with the updated base design.

In some embodiments, the method further includes receiving a request from a user of the industrial design application for a design for an industrial automation project. In some embodiments the method further includes sending to the user, in response to the request for a design, an initial layout of the industrial automation project. The initial layout includes the updated base design.

In some embodiments the method further includes receiving, from the user, a submission of a finalized layout of the industrial automation project, the finalized layout including one or more modifications of the initial layout. The method further includes providing the finalized layout to the GAI model for updating learned common selections among users of the industrial design application.

In some embodiments, the method further includes providing the GAI model with static data during initial training, the static data comprising one or more of: industrial product literature, industry standard data, existing base designs, and safety requirements data.

In some embodiments the generic base design includes an initial option pack. The initial option pack includes a plurality of options selectable by users of an industrial design application to configure an aspect of the industrial unit. The initial option pack includes a default selection of one of the plurality of options. The updated generic base design includes an updated option pack. The one or more differences include one or more differences between the initial option pack and the updated option pack.

In some embodiments the one or more differences between the updated option pack and the initial option pack include one or more of: a different default selection in the updated option pack compared to the initial option pack, a new option of the plurality of options in the updated option pack compared to the initial option pack, and a removed option of the plurality of options in the updated option pack compared to the initial option pack.

In some embodiments, the method includes determining whether the generic base design is from an open design library or one of a plurality of company design libraries. The open design library includes a plurality of generic base designs available to all users of the industrial design application. Each of the plurality of company design libraries includes one or more generic base designs available only to users affiliated with a specific company. The method further includes tailoring the prompt depending on the determining whether the generic base design is from an open design library or one of the plurality of company design libraries.

### BRIEF DESCRIPTION OF THE DRAWINGS

FIG. 1 illustrates a base design update system according to some embodiments.

FIG. 2 illustrates a schematic view of a base design according to some embodiments.

FIG. 3 illustrates a view of the cloud service of FIG. 1, according to some embodiments.

FIGS. 4A and 4B illustrate a method for updating generic base designs, according to some embodiments.

FIG. 5 illustrates an operational scenario for the base design update system of FIG. 1, according to some embodiments.

FIGS. 6A and 6B illustrate a method for updating option packs according to some embodiments.

FIG. 7 illustrates an operational scenario for the base design update system of FIG. 1, according to some embodiments.

FIGS. 8A-8D illustrate example user interfaces of an industrial design application, according to some embodiments.

FIG. 9 illustrates a prompt template, according to some embodiments.

FIG. 10 illustrates a computing system, according to some embodiments.

### DETAILED DESCRIPTION

This disclosure relates to the use of a Generative Artificial Intelligence (GAI) model, (e.g., a Large Language Model (LLM) or Multi-Modal Model (MMM)), to provide user-specific customization in an industrial design application. The industrial design application assists users in the design and procurement of industrial automation projects. Industrial automation projects may include one or more industrial automation devices. Individual industrial automation devices may include, for example, drives, controllers, conveyors, and the like. An industrial automation project may include, for example, Motor Control Centers (MCCs), power distribution systems, and factory lines. These projects may include a combination of industrial automation devices including industrial automation drives, industrial automation controllers, a cabinet for the industrial automation devices, and the like. An industrial design project for an entire factory may include all industrial automation devices needed to operate a factory. The industrial design application quickly provides users with unique designs for industrial automation projects and provides the users with the ability to easily customize the designs. The industrial design application may be utilized in the pre-sale phase of industrial automation projects. In the pre-sale phase, the user accesses the industrial design application to design the industrial automation project and request a quote.

The industrial design application includes a base design repository storing generic base designs, which are designs for fully functional industrial units. The generic base designs are selected and provided to users in response to requests for designs of industrial automation projects. The generic base designs are designed to align with common selections made by users of the industrial design application. For example, the generic base design may include a specific control scheme or operator station that users commonly select when designing industrial systems. However, certain selections made by users may become more or less popular over time. As such, an option in the industrial design application that was once an uncommon selection may become a common selection, and vice versa. As such, the database of industrial designs may become outdated.

The present disclosure describes leveraging the GAI model to update the generic base designs in the base design repository. Specifically, the industrial design application makes request for the GAI model to update the generic base designs based on common selections in industrial design submissions from users of the industrial design application. Accordingly, updated base designs received from the GAI model have configurations that are more likely to align with current common selections made by users of the industrial design application. This increases the case of use for users since the initial designs they receive are more likely to be aligned with industry standards. As such, the number of alterations that users need to make to arrive at their preferred design is usually decreased. Furthermore, novice users may not be as familiar with common selections in various industries. The model-updated base designs assist users in arriving at designs with optimal selections, even if the user would not otherwise have had the experience necessary to make optimal selections.

Additionally, resource usage may be reduced using the disclosed systems. For example, common selections for all possible configuration options for various industries and locations do not need to be individually determined and stored. Furthermore, the disclosed systems may reduce operational costs, since the GAI model may accurately identify common selections in real-time, reducing the need for database maintenance and data analysis processing operations.

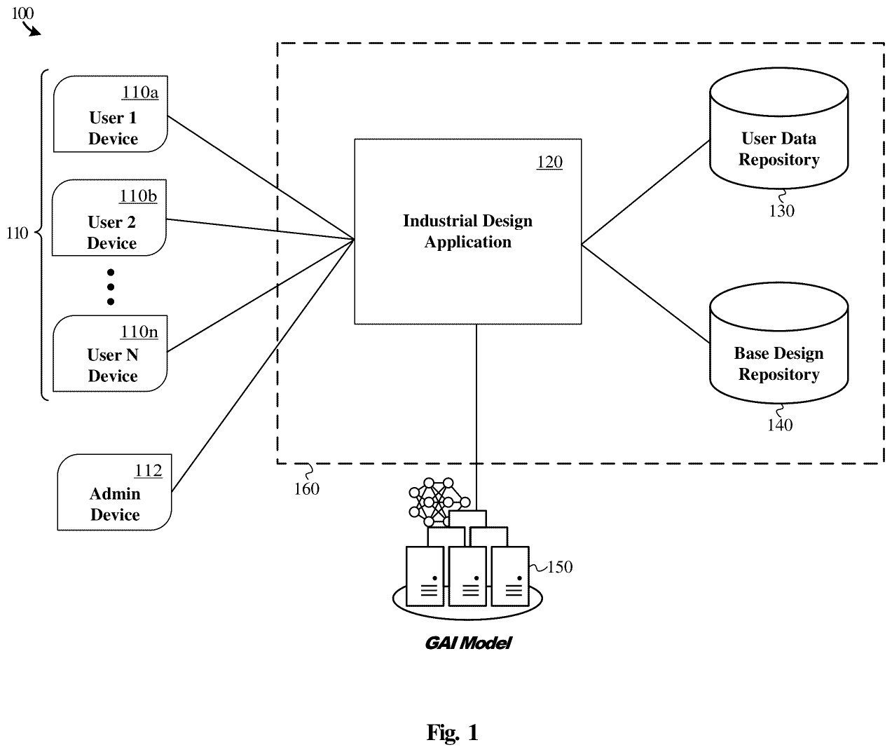

FIG. 1 illustrates system 100 according to some embodiments. System 100 includes user devices 110, admin device 112, cloud platform 160, and GAI model 150. While specific elements of system 100 are shown for case of description, system 100 may include more or fewer of each described component as well as other components not described for simplicity.

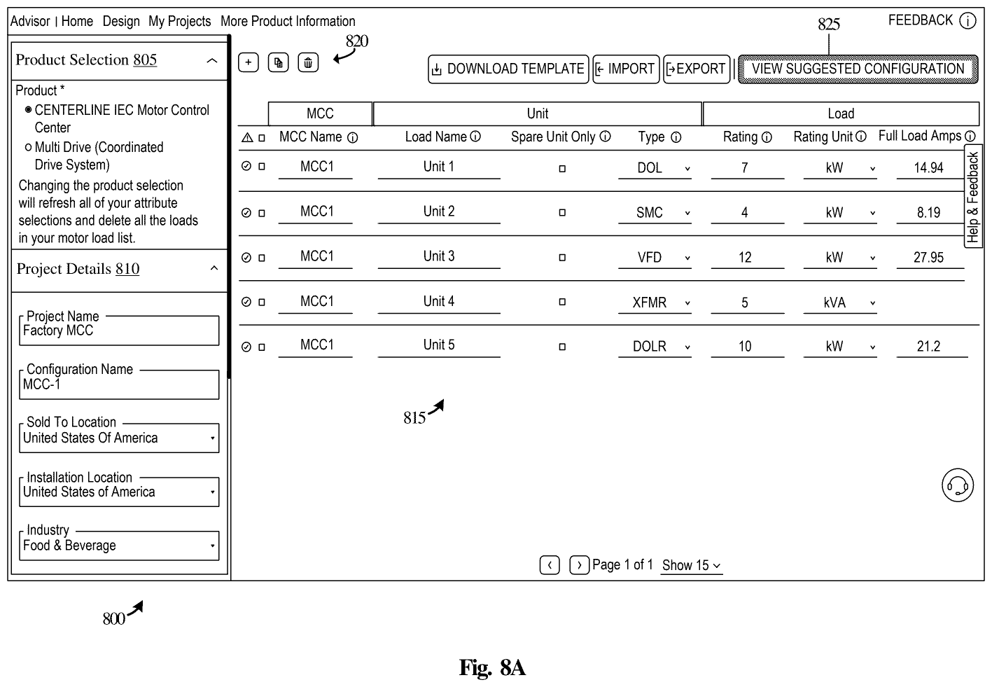

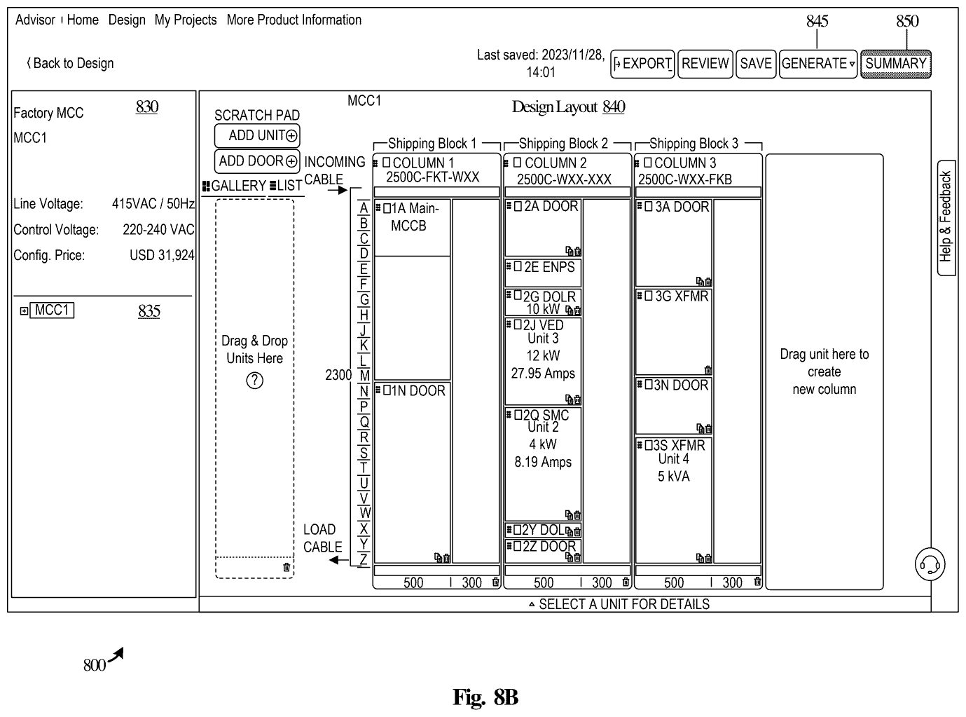

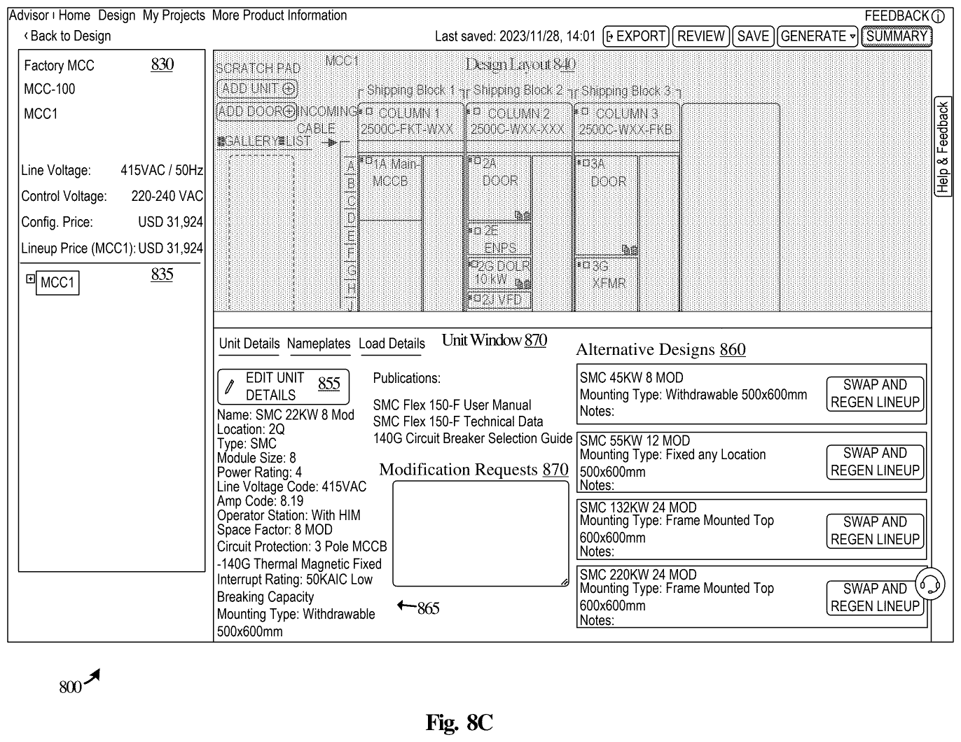

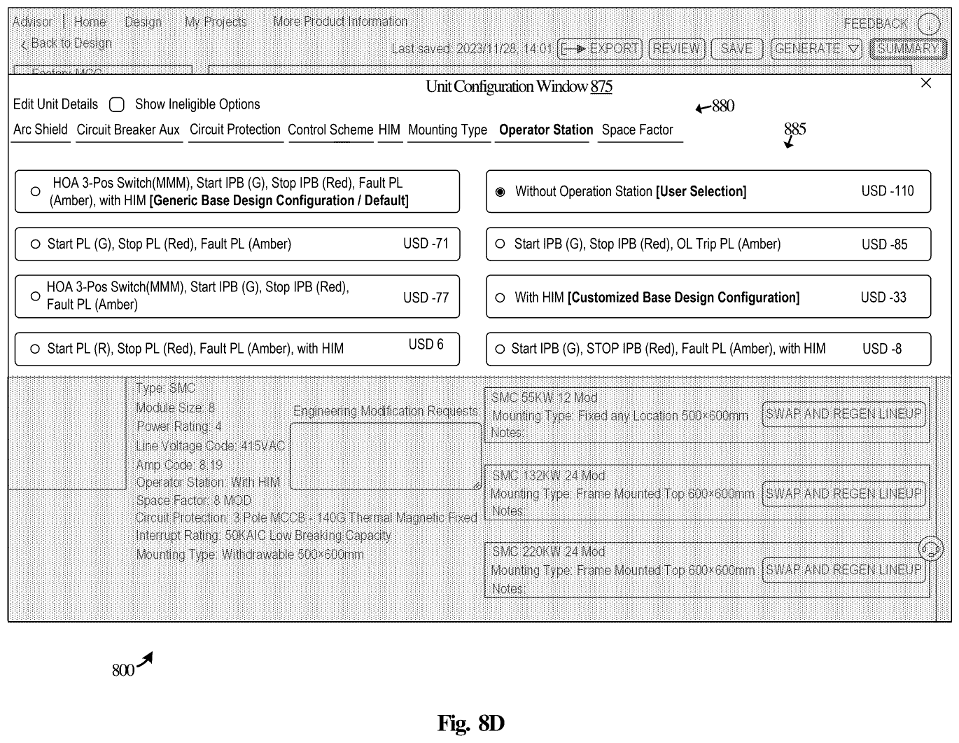

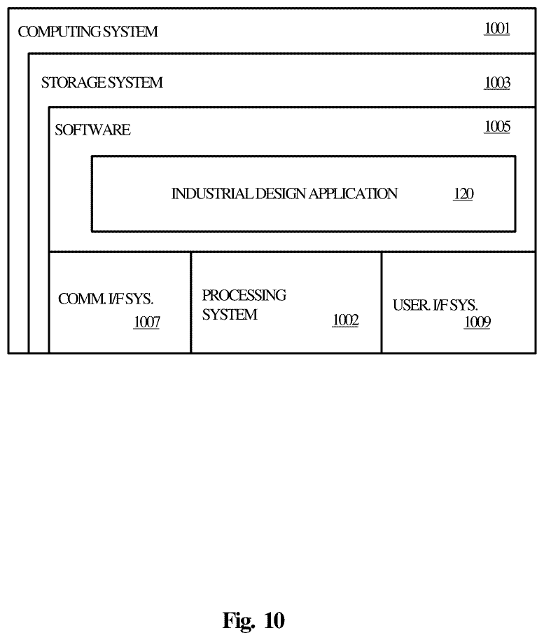

User devices 110 include user 1 device 110a, user 2 device 110b, and user N device 110n. While three user devices are shown in FIG. 1 for simplicity, system 100 may include any number N of user devices 110. User devices 110 may include computers, laptops, mobile devices such as smartphones or tablets, or any other similar device capable of interfacing with industrial design application 120. Users may access industrial design application 120 on user devices 110. Specifically, users may log into a user account on a web browser on the user device to access industrial design application 120. In some embodiments, the users may open an application program on user device 110 to access industrial design application 120. In either case, industrial design application 120 provides a user interface to display to the user on user device 110. Exemplary user interfaces 800 are shown in FIGS. 8A-8D. User devices 110 may be computing device 1001 described with respect to FIG. 10.

A user may interact with the user interface on user device 110 to make a request for a design of an industrial automation project. Such a request may be made in the pre-sale phase of the industrial automation project. The industrial automation project may include one or more industrial automation devices, including a layout of physical components for installation, for example, on a factory floor. In the pre-sale phase, the user may design and configure the industrial automation project using the user interface on user device 110. Once the user is satisfied with the industrial automation project design, the user may request a quote for the designed industrial automation project (i.e., each of the configured industrial automation devices in the industrial automation project).

To make the request for the design, the user may input parameters of the industrial automation project in the user interface of user device 110. In some embodiments, the parameters include the relevant industry (e.g., “Automotive” or “Food/Beverage”) and the installation location (e.g., country, city, region, or the like) in which the industrial automation project is to be implemented. Parameters may also include a load list, setting forth the functionality of the industrial automation project. When the industrial automation project is an MCC, the load list may be a motor-load list, in which the user inputs the types of motor controllers (e.g., Direct On Line Starter (DOL), Variable Frequency Drive (VFD), etc.) in the MCC, as well as other relevant parameters such as the power rating for each motor controller. Once the user has input the parameters, the user may submit the request for the design of the industrial automation project via the user interface of user device 110.

Generated designs for the industrial automation project are provided to users via the user interfaces of user devices 110, in response to design requests. The generated design includes one or more customized base designs and an arrangement of the customized base designs including physical placement, connections, and the like when appropriate. The customization of base designs is discussed in further detail below. Each customized base design is a design for a fully functional industrial unit, customized by GAI model 150 based on learned user preferences. A fully functional industrial unit may be a single industrial automation device (e.g., a programmable logic controller, a drive, or the like) or it may be a combination of industrial automation devices arranged into a common configuration (e.g., a motor control center (MCC)). The generated design may include a complete layout for a set of customized base designs. A generated design for an MCC is shown, for example, in FIG. 8B, which includes an arrangement of motor controllers in a series of columns. Once the user receives the design, the user may make modifications to the generated design, as discussed in detail in FIGS. 8C and 8D below. For example, the user may modify configuration options, remove or add base designs for one or more industrial units, or the like. Once the user is satisfied with the design of the industrial automation project, the user may submit the finalized project. The submission of the finalized project may include, for example, a request for a quote. Users may also interact with the user interfaces of user devices 110 to perform other tasks such as submitting feedback, viewing help topics, reporting bugs, requesting live customer assistance, and viewing product catalogues, for example.

Admin device 112 is used by administrators to perform administrative tasks in industrial design application 120. While one admin device 112 is shown in FIG. 1 for simplicity, system 100 may include multiple admin devices 112 utilized by multiple administrators of industrial design application 120. Admin devices 112 may include computers, laptops, mobile devices such as smartphones or tablets, or any other similar device. Administrators may access industrial design application 120 via user interfaces on admin devices 112. The user interfaces may be viewed, for example, in web browsers accessing industrial design application 120 remotely, in specialized locally installed applications that access industrial design application 120 remotely, or directly in a locally installed implementation of industrial design application 120. Administrators may request an update of a generic base design or an option pack of a generic base design, as discussed in methods 400 and 600 below. Admin devices 112 may be computing device 1001 described with respect to FIG. 10.

Cloud platform 160 includes industrial design application 120, user data repository 130, and base design repository 140. Cloud platform 160 may optionally include Generative Artificial Intelligence (GAI) model 150 in some embodiments. Cloud platform 160 operates from servers which may be located in data centers, distributed in various geographic locations, and the like. Various software components of cloud platform 160 may have multiple instances in different geographic locations for redundancy and speed.

Industrial design application 120 includes software operating from servers in cloud platform 160. Industrial design application 120 may be a web-based application that assists users in the design of industrial automation projects. Industrial design application 120 may be utilized in the pre-sale phase of industrial automation projects. In the pre-sale phase, industrial design application 120 is used to assist users in designing and configuring the industrial automation projects, and to provide quotes to the users for the industrial automation projects. Industrial design application 120 generates a design of industrial units (e.g., one or more industrial automation devices) based on parameters defined by the user. For example, in the process of assisting in the design of an MCC, industrial design application 120 may generate a layout of motor controllers and other components (e.g., circuit breakers and power buses) to meet the requirements of a user's design request.

Industrial design application 120 interacts with user devices 110, admin devices 112, user data repository 130, base design repository 140, and GAI model 150 to perform various functions as discussed below. Industrial design application 120 may be computer software implemented on one or more servers and/or in a cloud-based environment. Industrial design application 120 may be implemented in memory on a server such as, for example, computing device 1001 as described with respect to FIG. 10.

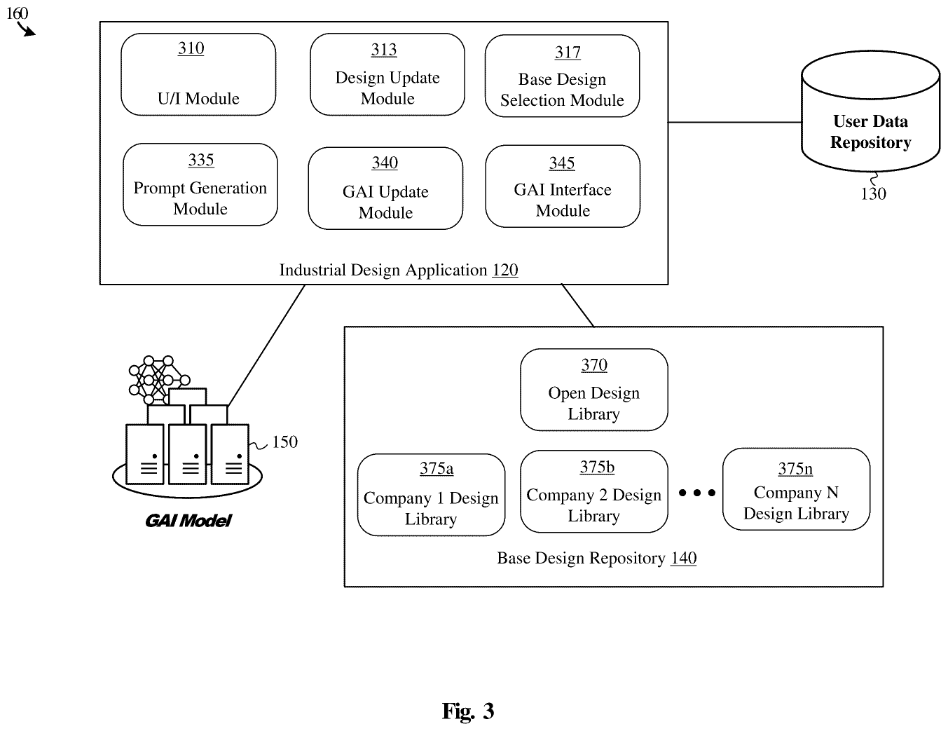

Industrial design application 120 receives requests from users for designs of industrial automation projects. Such requests may include parameters defined by users, as discussed above. Based on the parameters in the user request, industrial design application 120 selects generic base designs from base design repository 140 to include in an initial design of the industrial automation project. For example, in the case in which the request is for the design of an MCC, industrial design application 120 selects a generic base design for a motor controller for each load included in the motor-load list of the user's request. The selection of a generic base design is based on the type of motor controller requested (e.g., VFD) as well as other stated requirements (e.g., power ratings) in the parameters. Industrial design application 120 generates a layout for the industrial automation project including all the generic base designs selected. However, it is noted that industrial design application 120 may also prompt GAI model 150 to generate customized base designs before generating the layout, as discussed in further detail in related applications incorporated by reference above. Once the layout for the industrial automation project is generated, industrial design application 120 displays the layout to the user via the user interface of user device 110. Industrial design application 120 may receive design selections from the user, where the design selections are modifications of industrial design application 120 made by the user in the user interface of user device 110. Industrial design application 120 also initiates updates of the generic base designs and option packs of the generic base designs in base design repository 140, as discussed in greater detail in methods 400 and 600 below. Furthermore, FIG. 3 includes additional details of the functionalities performed by industrial design application 120.

User data repository 130 is a database storing information about each user of industrial design application 120. In some embodiments, user data repository 130 may include basic information about each user such as login information, contact information, and the user's organization or company. User data repository 130 may also include historical user data including previous industrial automation project design configurations submitted by the user, and previous industrial automation projects purchased by the user. This historical user data may be provided to GAI model 150 for user-specific training, as discussed in further detail in method 400 below. The user data in user data repository 130 may be stored in memory of a server or other data storage device of cloud platform 160.

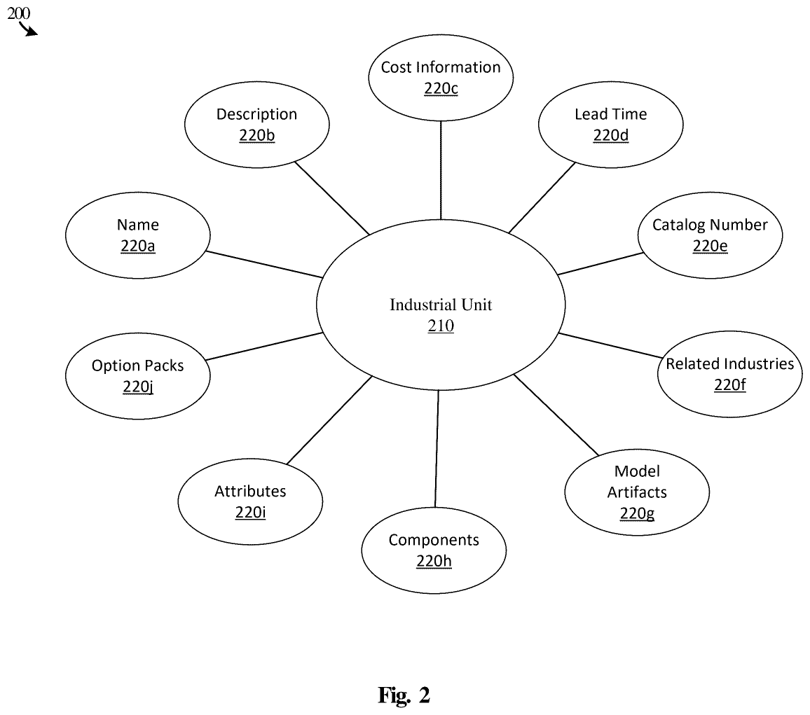

Base design repository 140 is a database that may contain generic base designs of industrial units. Industrial units include one or more industrial automation devices and are described in more detail with respect to FIG. 2. Each generic base design (generic base designs 390 described with respect to FIG. 3) in base design repository 140 includes a generic design configuration for a fully functional industrial unit. Generic base designs are described in more detail with respect to base design 200 of FIG. 2. Metadata for each generic base design, for example metadata 220 of FIG. 2, is stored in base design repository 140. The metadata includes detailed information defining a fully functional industrial unit, as discussed further in FIG. 2 below. The metadata may include option packs for the industrial units. Option packs (e.g., option packs 220j of FIG. 2) include various options for configurable aspects of the industrial unit. For example, a base design for a VFD could include an “Operator Station” option pack. A user may thus choose between different types of operator stations, such as an operator station having a Human Interface Module (HIM) or an operator station having a combination of a HIM and indicator lights. Each option pack may include a default selection. The metadata of the generic base designs are used by industrial design application 120 for generating the prompts for GAI model 150 requesting updates of generic base designs and option packs of generic base designs, as discussed in methods 400, 600 below. The generic base designs in base design repository 140 may be stored in memory of a server or other data storage device of cloud platform 160.

The generic base designs in the base design repository 140 are designed to be aligned with common configuration selections among users of the industrial design application 120. For example, in the textile industry, users often select fixed mounting for motor controllers to provide better sealing from particulate matter in the environment. As such, generic base designs with “textiles” as a relevant industry may generally include fixed mounting arrangements for motor controllers. With changing industrial design practices, some common selections may change over time. To keep the generic base designs in the base design up to date with current common selections, the industrial design application 120 leverages the GAI model 150 to update the generic base designs and option packs of generic base designs, as discussed in further detail in methods 400, 600 below.

GAI model 150 is a generative artificial intelligence model trained to perform industrial design tasks. GAI model 150 may include a system of transformer-based neural networks with a vast number of parameters (e.g., weights and balances). The parameters are adjusted during training for learning information, including industrial data and user specific preferences. Training GAI model 150 is discussed in further detail in method 400 below. GAI model 150 may be a large language model (LLM) trained on a vast amount of textual data. An LLM is capable of processing textual inputs to generate textual outputs. In some embodiments, GAI model 150 is a Multi-Modal Model (MMM). An MMM may be trained on a vast amount of various types of data, including, for example, textual data, video, audio, images, 3-D renderings, CAD files, and other various forms of media. An MMM may be capable of processing inputs and generating outputs in each of these formats. GAI model 150 may be implemented on a computing system (e.g., computing system 801 of FIG. 8), typically in a cloud-based environment due to the processing and memory resources needed to support GAI model 150. However, on-premises implementations are within the scope of this disclosure. Further, GAI model 150 is depicted outside of cloud platform 160. However, in some embodiments, GAI model 150 may be hosted within cloud platform 160, for example, as an enterprise-specific instance.

Industrial design application 120 leverages GAI model 150 to keep the generic base designs up to date with common industry preferences. As such, GAI model 150 may periodically update the generic base designs based on learned common industry preferences. The updating of generic base designs and option packs of generic base designs are discussed in in methods 400, 600 below. It is noted that GAI model 150 may also provide user-specific customization of base designs from base design repository 140, as discussed in greater detail in related applications incorporated by reference above.

GAI models (also known as foundation models) are models trained to generate new data based on a training dataset. GAI models as used herein include large-scale generative artificial intelligence (AI) models trained on massive quantities of diverse, unlabeled data. The GAI models learn using self-supervised, semi-supervised, or unsupervised techniques. GAI models perform many downstream tasks based on capturing general knowledge, semantic representations, and patterns and regularities in the training data. In some embodiments, such as embodiments included herein, a GAI model may be fine-tuned for specific downstream tasks. GAI models include BERT (Bidirectional Encoder Representations from Transformers) and ResNet (Residual Neural Network). GAI models may be based on any relevant architecture, including, for example, generative adversarial networks (GANs), variational auto-encoders (VAEs), and transformer models, including multimodal transformer models. Depending on the type of input accepted and output provided, GAI models may be multimodal or unimodal.

Multimodal models are a class of GAI models that accept multimodal data including text, image, video, and audio data. Multimodal models may leverage techniques like attention mechanisms and shared encoders to fuse information from different modalities and create joint representations. Learning joint representations across different modalities enables multimodal models to generate multimodal outputs that are coherent, diverse, expressive, and contextually rich. For example, multimodal models can generate a caption or textual description of a given image by extracting visual features using an image encoder, then feeding the visual features to a language decoder to generate a descriptive caption. Similarly, multimodal models can generate an image based on a text description (or, in some scenarios, a spoken description transcribed by a speech-to-text engine). Multimodal models work in a similar fashion with video-generating a text description of the video or generating video based on a text description.

Multimodal models include visual-language foundation models, such as CLIP (Contrastive Language-Image Pre-training), ALIGN (A Large-scale ImaGe and Noisy-text embedding), and VILBERT (Visual-and-Language BERT), for computer vision tasks. Examples of visual multimodal or foundation models include DALL-E, DALL-E 2, Flamingo, Florence, and NOOR. Types of multimodal models may be broadly classified as or include cross-modal models, multimodal fusion models, and audio-visual models, depending on the particular characteristics or usage of the model.

Large language models (LLMs) are a type of GAI model that process and generate natural language text. These models are trained on massive amounts of textual data. LLMs learn to generate relevant responses given a prompt or input text. The responses are coherent and contextually relevant to the given prompt. LLMs understand and generate sophisticated language based on their training. LLMs capture intricate patterns, semantics, and contextual dependencies in textual data. In some cases, LLMs may be used in multimodel models. For example, the LLM intelligence is used to combine images and audio input with textual input to generate multimodal output. Types of LLMs include language generation models, language understanding models, and transformer models.

Transformer models, including transformer-type foundation models and transformer-type LLMs, are a class of deep learning models used in natural language processing (NLP). Transformer models are based on a neural network architecture which uses self-attention mechanisms to process input data and capture contextual relationships between words in a sentence or text passage. Transformer models weigh the importance of different words in a sequence, allowing them to capture long-range dependencies and relationships between words. GPT (Generative Pre-trained Transformer) models, BERT (Bidirectional Encoder Representations from Transformer) models, ERNIE (Enhanced Representation through kNowledge Integration) models, T5 (Text-to-Text Transfer Transformer), and XLNet models are types of transformer models which have been pretrained on large amounts of text data using a self-supervised learning technique called masked language modeling. For example, large language models, such as ChatGPT and its brethren, have been pretrained on an immense amount of data across virtually every domain of the arts and sciences. This pretraining allows the models to learn a rich representation of language that can be fine-tuned for specific NLP tasks, such as text generation, language translation, or sentiment analysis. Moreover, these models have demonstrated emergent capabilities in generating responses that are creative, open-ended, and unpredictable.

In practice, industrial design application 120 may determine that a trigger has been satisfied for updating generic base design in base design repository 140. This determination may also be made for a or specific option pack, for example the “Operator Station” option pack of a VFD, as shown in option pack 880 of FIG. 8D. The determination that the trigger has been satisfied may be based on a determination that a predetermined time-period has elapsed. For example, the predetermined time-period may be one year, three months, or one month. It is noted that other time-periods may be used in various embodiments. The predetermined time-period is set to ensure that the option packs stay up to date with changing industry preferences. Some option packs of generic base designs may not need to be updated as often, since industry preferences for certain option packs may tend to stay stable. As such, various option packs may be associated with different pre-determined time periods. In some embodiments, the industrial design application 120 may also initiate an update of a generic base design based on a request received from admin device 112 to update one or more generic base designs selected from base design repository 140. For example, if preferences for a specific configuration are rapidly changing, an engineer may wish to request an update for a specific option pack associated with the configuration. The engineer may thus log into admin device 112 and submit a request to industrial design application 120 to update the specific option pack. Additionally, the determination that the trigger has been satisfied may be based on determining that the generic base design or option pack has been provided to users above a threshold number of times. The threshold number of times may be any number (e.g., on the order of hundreds or thousands) indicating that the generic base design is a design is commonly provided to users.

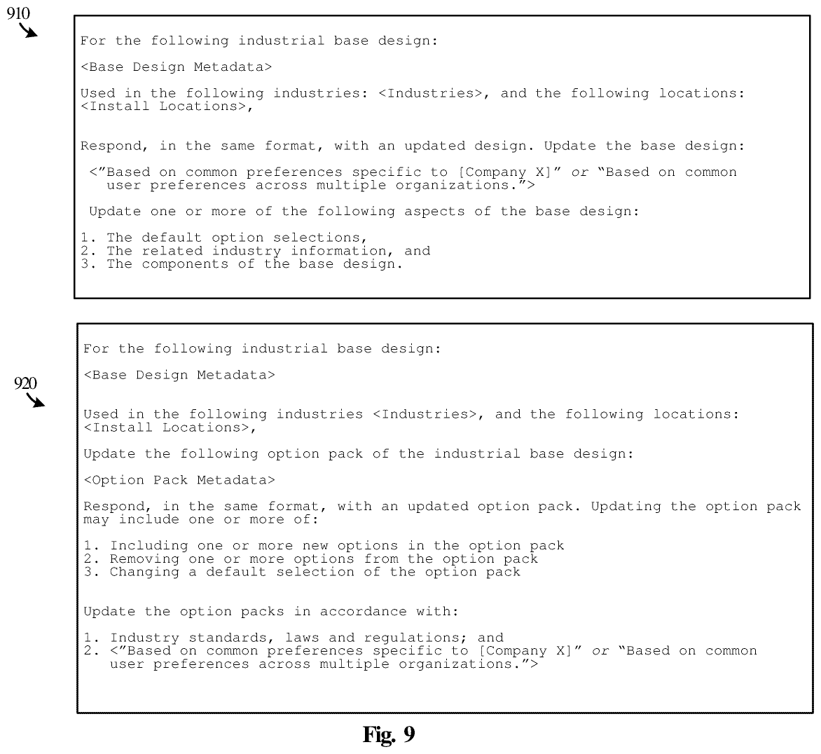

When the determination has been made that the trigger is satisfied, industrial design application 120 generates a prompt for GAI model 150 to update the generic base design or option pack. The prompt may be generated using a prompt template, such as prompt templates 910, 920 of FIG. 9.

The prompt is sent to GAI model 150. Upon receiving the prompt, GAI model 150 generates an updated generic base design or option pack based on common selections for the relevant industries and locations. For example, the GAI model may have learned users never choose one of the options, such as the “Start PL (G), Stop PL (Red), Fault PL (Amber)” option in option pack 880 of FIG. 8D. As such, the updated option pack may have this removed as an option in the option pack. Alternatively, certain options may be hidden or excludable from option packs such that they are not visible to users viewing the option pack. Such options may be hidden for various reasons-including not aligning with industry preferences or industrial standards such as safety standards. However, the GAI model 150 may have learned that these hidden options have, over time, become aligned with industry standards and/or preferences. As such, the updated option pack may include the previously excluded options in the option pack, such that in the future users may view and select the options. Finally, the updated option pack may include a different default selection than the initial option pack.

Once GAI model 150 generates the updated generic base design or option pack, GAI model 150 responds to industrial design application 120 with the updated option pack. The updated option pack may then be provided to an administrator or engineer, such as an engineer on admin device 112, to review the updated option pack. The engineer may review the updated base design to ensure it meets quality standards. If the engineer approves of the updated option pack, the engineer sends an indication of approval to industrial design application 120. Industrial design application 120 will then replace the original generic base design with the updated base design having the updated option pack generated by GAI model 150. The updated base design may then be provided as initial suggestions in response to future requests by users to generate an industrial automation system design. As such, the base designs and the option packs in the base designs provided to users will be closely aligned with current industry preferences, thus increasing the quality of designs created by users and increasing the case of use of the application. In some embodiments, the original base design may remain in base design repository 140 along with the updated base design until an administrator reviews the original base design. Upon review, an administrator may determine to remove the original base design (e.g., if it has become outdated) or keep in in base design repository 140 as an alternative to the updated base design. As such, industrial design application 120 does not remove the original base design without administrator approval, according to some embodiments.

FIG. 2 illustrates a schematic view of base design 200 according to some embodiments. Base design 200 contains detailed design data about a specific industrial unit 210. Base design 200 of FIG. 2 may be representative of the generic base designs stored in base design repository 140 of FIG. 1. Base design 200 may also be representative of the customized base designs provided to users, as described in related applications incorporated by reference above. Base design 200 includes industrial unit 210 and metadata 220. Metadata 220 includes name 220a, description 220b, cost information 220c, lead time 220d, catalog number 220e, related industries 220f, model artifacts 220g, components 220h, attributes 220i, and option packs 220j. Metadata 220 may be representative of metadata in base design 200, however base design 200 may include additional metadata 220 or less metadata 220 without departing from the scope of the present disclosure.

Industrial unit 210 of base design 200 represents a design for a fully functional industrial unit 210. Industrial unit 210 may be represented in a CAD file or blueprint stored in base design repository 140. In the context of an MCC, industrial unit 210 may be, for example, an industrial automation device such as a circuit breaker, a drive, or any other industrial unit 210 included in an MCC. Industrial unit 210 may include sub-components, in some examples. For example, a Direct On-Line (DOL) motor controller may include an arrangement of auxiliary contacts. In addition to the sub-components, the DOL may include other parameters including, for example, a control scheme, a mounting type, an operator station, a specific overload type, and a safety category. Industrial unit 210 may also be a broader unit such as a cabinet of an MCC, with an arrangement of various motor controllers and other components such as power buses within the cabinet. In an even broader sense, industrial unit 210 may be a fully functional MCC, with an arrangement of motor controllers and other industrial automation devices, arranged with relevant connections, in multiple cabinets. As such, base design 200 may define various levels of designs, from individual industrial automation devices (e.g., circuit breakers) to an entire factory of industrial automation devices including their connections and relationships, and everything in between (e.g., an MCC). Base design 200 may be provided to users in response to requests from users to generate an industrial automation project. For example, if a user makes a request for a design of an MCC, industrial design application 120 may generate a design for an MCC by selecting several base designs 200, requesting customized base designs from GAI model 150, and generating a layout of the customized base designs to create a fully functional MCC design customized for the specific user. Alternatively, base design repository 140 may include a base design for an MCC that can be customized by GAI model 150 to meet the parameters of the user's request based on the generated prompt. In either case, a user-specific customized design for a fully functional MCC may be generated. A user may further modify the design once the user views the design in industrial design application 120 by changing various selectable options within the design.

Metadata 220 collectively refers to metadata 220a-220j of base design 200. Metadata 220 includes detailed information about industrial unit 210, which may be stored in one or more taxonomy files. The taxonomy files may include spreadsheets, CAD files, electrical schematic blueprints, and other diagrams and file types for storing the information about industrial unit 210. Specific examples of metadata 220 are provided, but any variation may be used to describe industrial unit 210 without departing from the scope of the present disclosure.

Metadata 220 may include name 220a of industrial unit 210. Name 220a may include, for example, the unit type (e.g., VFD) in addition to an identifying model number. In other examples, a model number, a type of device, or any other name may be used.

Metadata 220 may further include description 220b. Description 220b may include high-level information about the unit, as shown, for example, in the high-level overview of the configuration list 865 of FIG. 8C. Description 220b may also include detailed industrial specifications for the unit.

Metadata 220 may further include cost information 220c indicating the cost of industrial unit 210, including various price changes for selections of different selectable options, for example, within option packs 220j discussed below.

Metadata 220 may further include lead time 220d, the time-interval between the purchase and delivery of the industrial unit 210.

Metadata 220 may further include one or more catalog numbers 220e associated with the unit. Catalog numbers 220e identify industrial unit 210 and are used for organizing industrial units in a product catalog.

Metadata 220 may further include related industries 220f, indicating which industries the industrial unit design is suitable for (for example, the metals industry or the food and beverage industry).

Metadata 220 may further include model artifacts 220g. Model artifacts 220g include models of industrial unit 210 and may include, for example, CAD files, electrical schematics, single-line diagrams, and mechanical models of industrial unit 210. Model artifacts 220g may further include a layout of industrial unit 210 illustrating, for example, how industrial unit 210 is laid out in a grid.

Metadata 220 may further include components 220h, including information about the subcomponents included in industrial unit 210. For example, some of the subcomponents of a motor controller may include control circuitry, an operator station, a circuit breaker, and a housing.

Metadata 220 may further include attributes 220i, storing information about the capabilities of industrial unit 210, such as maximum power ratings.

Metadata 220 may further include option packs 220j. Metadata 220 may include one or more option packs 220j, where users can select various options within each option pack. An example option pack is represented in FIG. 8D. Alternatively, when the base design is a design for an MCC cabinet or an entire MCC, the option pack may include information about various substitutable components (such as motor controller models that are substitutable for the motor controller models included in the base design). Each option pack may have a default selection. In generating customized base designs, the GAI model 150 may make alternate selections of options within option packs based on learned user preferences. As noted above, metadata 220 included in FIG. 2 is representative only; other embodiments may include additional elements, fewer elements, or any combination of various elements.

In practice, base design 200 may be a generic base design stored in base design repository 140, such as base design repository 140 of FIGS. 1 and 3. Industrial design application 120 retrieves some or all metadata 220, for inclusion in a prompt for GAI model 150. Industrial design application 120 includes some or all metadata 220 in a prompt requesting an update of base design 200 based on common selections made by users of industrial design application 120. GAI model 150 responds to industrial design application 120 with updated metadata aligning with learned common design selections made by users. Industrial design application 120 then updates base design 200 by replacing original metadata 220 with the updated metadata in base design repository 140.

FIG. 3 shows cloud platform 160 according to some embodiments. The cloud platform 160 includes industrial design application 120, user data repository 130, base design repository 140, and GAI model 150. Note that GAI model 150 is depicted as part of cloud platform 160 in FIG. 3, however, this is an optional configuration as discussed above with respect to FIG. 1. GAI model 150 may be hosted within cloud platform 160 or externally without departing from the spirit and scope of this disclosure.

User data repository 130 is a database storing information about each user of industrial design application 120. User data repository 130 includes basic information about each user including login information, contact information, and the user's organization or company. The user data repository may also include historical user data including previous industrial design configurations submitted by the user, and previous products purchased by the user. The historical data in user data repository 130 may be used to train GAI model 150 to learn user-specific preferences for each user, as well as common industrial preferences.

Base design repository 140 is a database of generic base designs. In some embodiments base design repository 140 may include open design library 370. Open design library 370 is a library of generic base designs that may be provided to any user of industrial design application 120 regardless of company affiliation. Base design repository 140 also contains company specific design libraries including Company 1 Design Library 375a, Company 2 Design Library 375b, and Company N Design library 375n (collectively “Company Design Libraries 375” for N number of companies). For example, Company 1 Design Library 375a contains generic base designs specific to Company 1, Company 2 Design Library 375b contains generic base designs specific to Company 2, and Company N Design Library 375n contains generic base designs specific to Company N (for any number N of companies that have specific design libraries). Storing company specific generic base designs allows industrial design application 120 to provide company specific customization to users of industrial design application 120. For example, a specific company may design preferences that are not commonly practiced by designers in other organizations. Furthermore, this arrangement allows for the protection of intellectual property such as trade secrets, as a company specific generic base design will not be provided to users who are not affiliated with the company.

Base design repository 140 may include any number of generic base designs. For example, in various embodiments, base design repository 140 may include on the order of hundreds or thousands of generic base designs. Each generic base design is stored either in Open Design Library 370 or one of Company Design Libraries 375. The generic base designs may be base design 200 of FIG. 2. Generic base designs are designs of fully functioning industrial units (e.g., Industrial Unit 210 described in detail with respect to FIG. 2) which may be included in an industrial automation project. Each generic base design may include an arrangement of sub-components including control components, operator interface components, and mounting components. Taxonomy files associated with each base design may include details about the base design including cost information, bill of materials (BOMS) for the base design, and option packs. In the context of an MCC, a base design may be a power component, or a motor control unit tailored for a specific application. For example, a base design may be motor control unit tailored for a specific type of pump, conveyor, or mixer in an industrial environment.

Each generic base design in base design repository 140 is a starting point for an industrial unit in a user's industrial automation project. Specifically, each generic base design includes a default configuration including default selections for configurable attributes. As described in method 400 below, industrial design application 120 leverages GAI model 150 to update the generic base designs in base design repository 140. The updates to the generic base designs may include, for example, updating default selections of configuration options, updating related industry information, or updating components within the generic base design. It is noted that these examples of updates to the generic base designs are exemplary; the updating of the generic base designs may include other types of modifications to the metadata of the generic base designs.

As an example, a generic base design for a Variable Frequency Drive (VFD) may include the model of VFD, the type of circuit breaker (e.g. thermal-magnetic), a mounting type (e.g., withdrawable or fixed), the interrupt rating, a space factor indicating the amount of space the VFD will occupy in a cabinet, a type of operator station (e.g., the inclusion of door pushbuttons, indicator lights, and Human Interface Modules), the type of Human Interface Module (HIM if a HIM is used), whether or not an EMC (Electromagnetic Compatibility) filter is included, the type of line reactor, and the safety category. GAI model 150 may update the base design of the VFD to have different default selections for one or more of the configurable attributes have different selections than the selections in the generic base design. For example, the initial generic base design may include a thermal-magnetic circuit breaker. GAI model 150 may have learned, based on training and feedback, that users usually switch to an electronic circuit breaker. Thus, when GAI model 150 receives a request to update the generic base design for the VFD, GAI model 150 may update the VFD to include an electronic circuit breaker as the default selection, to align with common selections made by users. As another example, the generic base design for the VFD may include several related industries. GAI model 150 may have learned that users in a certain industry such as the Food and Beverage industry usually swap out the VFD for a different model. As such, GAI model 150 may remove the Food and Beverage from this list of related industries when it updates the generic base design.

Each generic base design may be designed by an engineering team to be tailored to a specific application. Generic base designs may also be generated by GAI model 150 and reviewed by engineers before being added to base design repository 140. Due to the vast number of possible combinations of the configurable attributes, it is impractical to store every possible configuration as a generic base design. Rather, the generic base designs are starting points from which the user may further configure to arrive at their desired design. It is noted that in some embodiments, GAI model 150 may also generate user-specific customized base designs based on the generic base designs, as described in greater detail in related applications incorporated by reference above.

GAI model 150 is a large artificial intelligence model trained to perform industrial design tasks for industrial design application 120. GAI model 150 may be an LLM or an MMM as discussed above. GAI model 150 may include multi-layered transformer architecture with many parameters (e.g., weights and biases) encoding information. GAI model 150 may be created by training a base model to perform industrial design functions. Such a base model may be licensed and hosted by a third party. Alternatively, the base model may be purchased or provided as an open-source model. Base models have generally been pre-trained on a vast amount of data. However, even though a base model may be pre-trained, it is generally not specifically trained to perform industrial design tasks. As such, initial training to perform industrial design functions may be performed to fine-tune the model to perform industrial design tasks. After the initial training, the model may be further trained to provide user-specific customizations. The training process for GAI model 150 is discussed in greater detail below.

GAI model 150 generates updated generic base designs and updated option packs of generic base designs for base design repository 140. Prompts for GAI Model 150 are generated by Prompt Generation Module 335. A prompt generated by Prompt Generation Module 335 may indicate a request for GAI model 150 to update a generic base design or an option pack of a generic base design.

Upon receiving the prompt, GAI model 150 updates the generic base design or the option pack of the generic base designs in base design repository 140. Updates to the option packs may include, for example, updating default selections of within option packs, removing an option from an option pack, or adding a new option to the option pack.

As an example, the option packs for a Variable Frequency Drive (VFD) may include the Arc Shield, the Circuit Breaker Aux Contacts, the Circuit Protection Type, the Control Scheme, the type of HIM (if a HIM is used), the Mounting Type, the Operator Station, and the Space Factor, as shown in example option packs 880 in FIG. 8D. In the example shown in FIG. 8D, the “Operator Station” option pack is selected and eight different options within the option pack are displayed in selectable options 885. GAI model 150 may update one or more of the option packs within the VFD to have different default selections, to include a new option (that was previously excluded or hidden) or to remove an option. For example, GAI model 150 may have learned, based on training and feedback, that users never select “Start PL (G), Stop PL (Red), Fault PL (Amber).” As such, the updated option pack generated by GAI model 150 might not include this as an option in the updated option pack Furthermore, GAI model 150 may have also learned that there is a widespread user preference for an option not listed in FIG. 8D. GAI model 150 may have learned this, for example, from previous user selections in similar components, or from previous user requests to include an unlisted option. For example, there may be a growing preference for an operator station having both an HOA 3-Position Switch and a HIM without other components. Thus, the updated option pack generated by GAI model 150 may include a new option in the option pack to reflect this preference, such that users may select the option rather than making a special request for an operator station with a 3-Position Switch and a HIM. Finally, GAI model 150 may have learned that certain options are more widely used than the default option of the option pack. While the original default option may remain popular enough to remain in the option pack as a potential option for users, another option may be more popular. For example, in FIG. 8D, the selection “With HIM” may have become more popular than the original default option “HOA 3-Pos Switch, Start IPB, Stop IPB, Fault PL, with HIM.” Thus, the updated option pack generated by GAI model 150 may include “with HIM” as the default option, while leaving the previous default option as an option selectable by users. The default option is often presented to users as the initial configuration in industrial design application 120 (especially where there are not applicable user-specific preferences that can be used by GAI model 150 to customize the base design).

While GAI model 150 is described here as updating generic base designs and option packs of generic base s, it is noted that GAI model 150 may also perform other industrial design tasks. For example, GAI model 150 may be trained to generate user-specific customized base designs, to review user selections, to update the generic base designs, to generate new generic base designs for emerging industries, and provide product matching functions. These functions are described in greater detail in related applications incorporated by reference above.

Industrial design application 120 interfaces with user data repository 130, base design repository 140 GAI model 150, user devices 110 (not shown in FIG. 3, see FIG. 1). Industrial design application 120 includes User Interface (U/I) Module 310, Design Update Module 313, Base Design Selection Module 317, Prompt Generation Module 335, GAI Update Module 340, and GAI Interface Module 345. Further, while these modules are depicted to describe the generation of design layouts of the industrial design application, the functionalities described may be incorporated into more or fewer components, software components, hardware components, firmware components, or a combination without departing from the scope and spirit of the present disclosure. Each of the modules is discussed in turn below.

User Interface (U/I) Module 310 interacts with user devices 110. U/I Module 310 sends information for rendering the user display on user device 110. U/I Module 310 receives design selections and other inputs from users for designs of industrial automation projects (for example: requests for quotes, process requests for customer assistance, and process customer feedback comments). U/I Module 310 may also receive a request for a design including several user-selected parameters. In the case of an MCC, the user request may include a motor-load list, in addition to the industry and installation location for the MCC.

Base Design Selection Module 317 selects generic based designs from base design repository 140 based on parameters set forth in requests for designs received from users. A layout including the selected generic base designs may be provided to the user on user device 110 via U/I Module 310. An example initial layout is represented in FIG. 8A. The generic base designs selected by be updated generic base designs, or generic base designs with updated option packs, as described herein. Once Base Design Selection Module 317 selects the base designs, it retrieves the selected base designs from base design repository 140 to provide to the user via U/I Module 310.

Design Update Module 313 makes determinations that triggers have been satisfied for updating generic base designs and option packs of generic base designs in the base design repository 140. In one example, Design Update Module 313 initiates an update by determining that a predetermined time-period has elapsed since the last update of the generic base design. As such, Design Update Module 313 monitors the length of time that has elapsed since the last update for each generic base design in base design repository 140. When the predetermined time-period has elapsed for a specific generic base design, Design Update Module 313 initiates an update of that generic base design. The predetermined time-period is any time-period necessary to ensure that the generic base design stays up to date with industry preferences. The predetermined time-period may be, for example, one month, three months, or one year. An update of a generic base design may also be initiated, for example, by request from an administrator. Specifically, an administrator on admin device 112 (see FIG. 1) may send a request to industrial design application 120 to update a generic base design in base design repository 140 based on common selections among users. Additionally, the determination that the trigger has been satisfied may be based on determining that the generic base design or option pack has been provided to users above a threshold number of times. The threshold number of times may be any number (e.g., on the order of hundreds or thousands) indicating that the generic base design is a design is commonly provided to users.

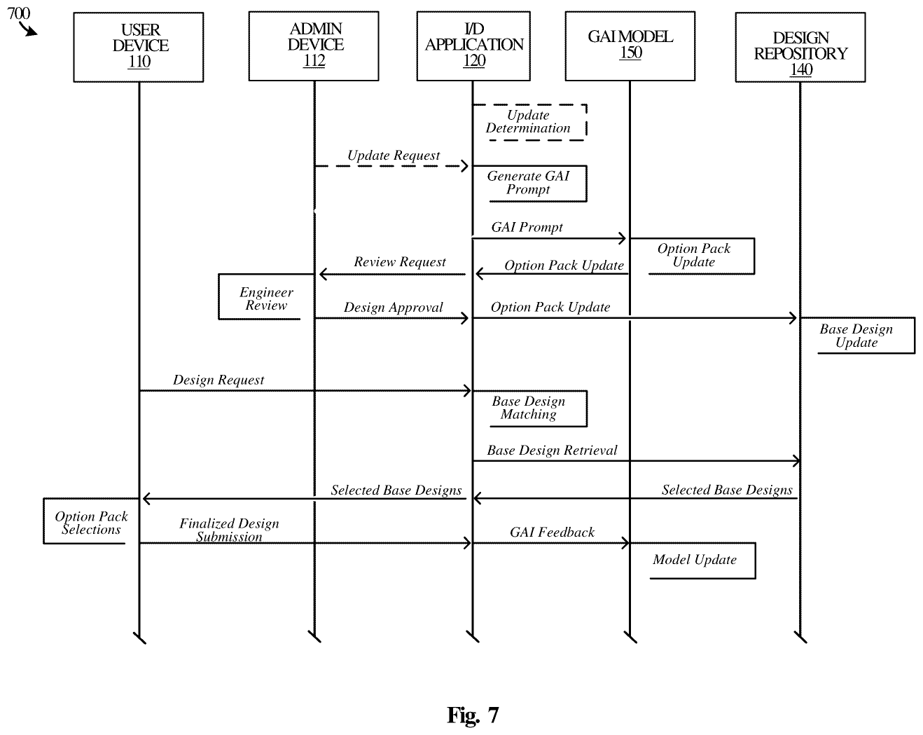

Once Design Update Module 313 determines that the trigger for updating the option pack has been satisfied, Prompt Generation Module 335 generates a prompt for GAI model 150. Prompt Generation Module 335 uses a prompt template, such as prompt template 910 of FIG. 7, to generate the prompt. To generate the prompt, Prompt Generation Module 335 retrieves metadata of the generic base design (e.g., metadata 220 of FIG. 2) from base design repository 140 and inserts the data into prompt template 910. The prompt generation using prompt template 910 is discussed in greater detail in FIG. 9 below.

Design Update Module 313 also updates base design repository 140 upon receipt of an approval from an engineer of updated base designs and updated option packs. This may include, for example, replacing the generic base design with the updated base design (as discussed in steps 415, 417 of method 400 below) or updating an initial option pack with the updated option pack (as discussed in steps 615, 617 of method 600 below).

Prompt Generation Module 335 generates prompts for GAI model 150. Prompt Generation Module 335 uses prompt templates, such as prompt templates 910, 920 of FIG. 9, to generate the prompt. The prompt templates may include a combination of text and placeholders, as shown in exemplary prompt templates 910, 920 of FIG. 9. Various prompt templates may be stored in a memory storage of Prompt Generation Module 335, each prompt template being associated with a specific task for GAI model 150 (e.g., review of design selections, base design updates, base design customization, etc.). During prompt generation, the Prompt Generation Module 335 selects an appropriate prompt template from the memory storage. For example, when Design Update Module 313 initiates an update of a generic base design, Prompt Generation Module 335 selects a prompt template for requesting a base design update from GAI model 150, such as prompt template 910 of FIG. 9. Alternatively, when Design Update Module 313 initiates an update of an option pack, Prompt Generation Module 335 selects a prompt template for requesting an option pack update, such as prompt template 920 of FIG. 9. When U/I Module 310 receives a design selection from a user of industrial design application 120, Prompt Generation Module 335 selects a prompt template for requesting GAI model 150 to review design selections, such as prompt template 920 of FIG. 9.

Prompt Generation Module 335 may select a base design update prompt template, such as prompt template 910 of FIG. 9, when Design Update Module 313 initiates a base design update. To generate the prompt for an update of a generic base design, Prompt Generation Module 335 retrieves some or all the metadata for the generic base design from base design repository 140 for insertion into the prompt template. The metadata for the generic base design may be metadata 220 of FIG. 2. In some embodiments, Prompt Generation Module 335 may retrieve all metadata 220 stored in base design repository 140. However, in other embodiments, Prompt Generation Module 335 only retrieves some of metadata 220. It is noted that there may be some stored metadata 220 for generic base designs that has comparatively less relevance with respect to updating the base designs. For example, Catalog Number 220e may have reduced relevance in the generation of updated base designs. Other metadata 220 such as option packs 220j, components 220h, and related industries 220f, are more relevant contextual information for GAI model 150 to generate design updates. As such, Prompt Generation Module 335 may retrieve these metadata while not retrieving metadata with lower relevance. By retrieving the more relevant metadata for inclusion in prompts, Prompt Generation Module 335 generates more focused prompts for GAI model 150. Once the metadata is retrieved, Prompt Generation Module 335 inserts the metadata design into a placeholder of the prompt template, such as “Base Design Metadata” placeholder prompt template 910 of FIG. 9. In the case of an option pack update, Prompt Generation Module 335 may insert option pack metadata (e.g., option packs 220j metadata of FIG. 2).

When generating a prompt requesting a base design update or an option pack update, Prompt Generation Module 335 may tailor the prompt depending on whether the generic base design is in Open Design Library 370 or Company Design Library 375. If the generic base design is in Open Design Library 370, the prompt may be tailored request a base design update based on common user preferences across multiple organizations, while if the generic base design is in Company Design Library 375, the prompt may be tailored to request a base design update based on common preference specific to the associated company. An example of a placeholder for tailoring the prompt is portrayed in the third placeholder in prompt template 910 of FIG. 9. This prompt tailoring prevents company-specific preferences from being applied to designs that are provided to users outside of the company, thus preserving proprietary information such as trade secrets.

GAI Interface Module 345 interfaces with GAI model 150 to provide prompts to GAI model 150 and receive responses from GAI model 150. Once Prompt Generation Module 335 generates a prompt as discussed above, GAI Interface Module 345 submits the prompts to GAI model 150. GAI Interface Module 345 also receives, from GAI model 150, responses to the submitted prompts. In the case of a base design update, GAI Interface Module 345 may receive updated metadata for an updated base design generated by GAI model 150. Upon receiving the updated metadata, GAI Interface Module 345 may perform initial validation for the updated metadata, including checking for corrupted data, checking syntax, and checking validity (e.g., checking that components included in the updated base design are valid components for the base design). Once GAI Interface Module 345 performs the initial validation, U/I Module 310 may provide the updated base design to an engineer (e.g., on admin device 112) for review, as described in step 413 of method 400.

GAI Update Module 340 continually provides new data to GAI model 150 to update GAI model 150 over time. In some embodiments, GAI Update Module 340 provides GAI model 150 with finalized designs for industrial automation projects submitted by users. Finalized designs submitted by users are received by U/I Module 310, as discussed above. The finalized designs include detailed information about the configuration of the industrial automation project, including the industry, the install location, and all industrial design selections made by the user of industrial design application 120. GAI model 150 updates learned information based on the finalized designs from the users of industrial design application 120. For example, GAI model 150 may learn, from processing finalized designs submitted from many users, that a certain selection has become more popular in a specific industry or country (e.g., engineers in Canada now select higher space factors for MCCs due to new regulations). As such, by continually providing GAI model 150 with finalized designs submitted by users, GAI model 150 stays up to date with current preferences in various industries and locations.

GAI Update Module 340 may also provide GAI model 150 with other new industrial information in addition to the finalized designs submitted by users. For example, GAI Update Module 340 may provide GAI model 150 with new industrial product literature, new industry standard data, and new safety requirements data. GAI Update Module 340 thus continually fine-tunes GAI model 150 to learn current industry standards, such that GAI model 150 may accurately update the base designs and review industrial design selections.

In practice, Design Update Module 313 determines that a trigger has been satisfied for initiating an update of a generic base design or an option pack of a generic base design in base design repository 140. The initiation of the update is based on a predetermined time-period elapsing since or an administrator's request for a base design update (received, for example, from admin device 112 of FIG. 1). Prompt Generation Module 335 retrieves metadata associated with the generic base design from base design repository 140 and generates a prompt requesting an updated base design based on common user selections for similar applications (e.g., similar industries and install locations), where the prompt includes the metadata. GAI Interface Module 345 submits the prompt to GAI model 150. GAI model 150 generates an updated base design based on common user selections in relevant industries and installation locations associated with the generic base design and responds to industrial design application 120 with updated metadata for an updated base design. GAI Interface Module 345 receives the updated metadata. U/I Module 310 provides the updated metadata of the updated base design to an administrator on admin device 112. The administrator reviews the updated base design. If the administrator indicates approval of the updated base design, U/I Module 310 receives the administrator's approval of the updated base design. Design Update Module 313 adds the updated base design to base design repository 140.

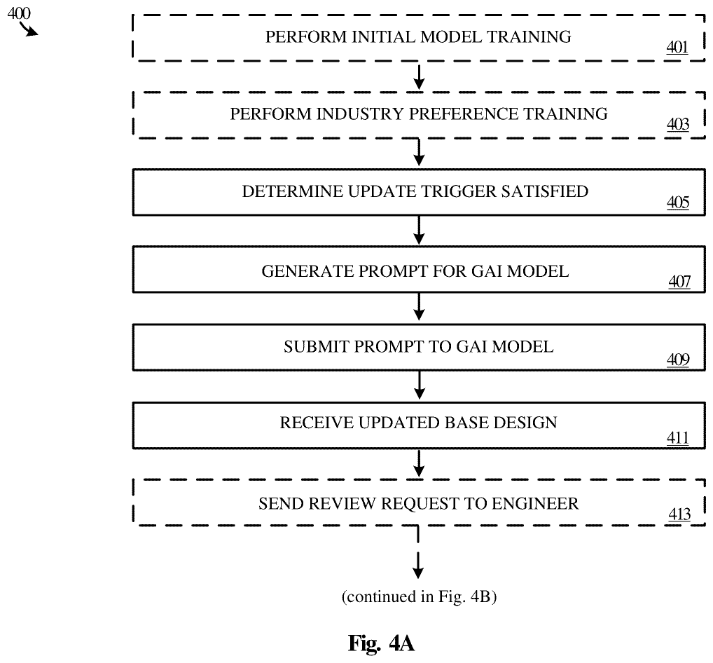

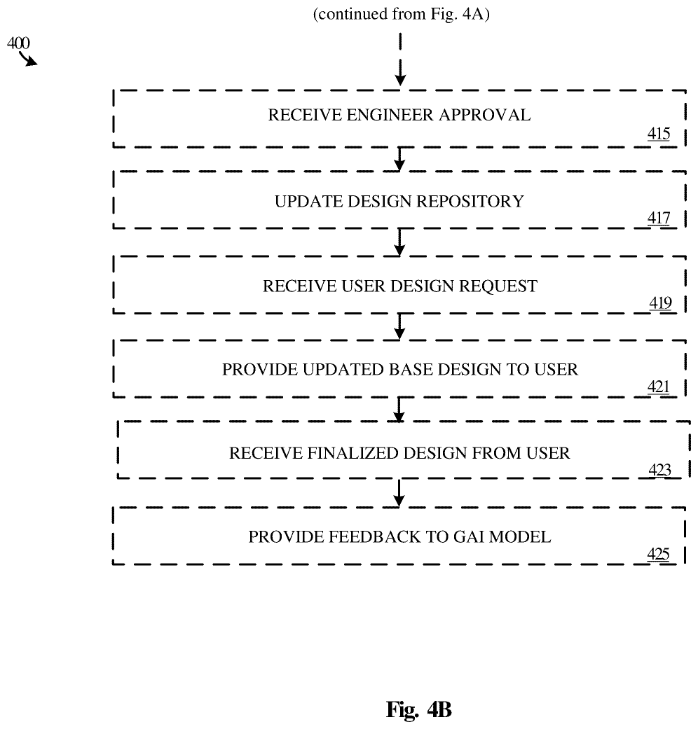

FIGS. 4A and 4B illustrates computer-implemented method 400 for updating base designs performed according to some embodiments.

Step 401 of method 400 is performing initial GAI model training. Step 401 may be performed by GAI Update Module 340 of FIG. 3. In training GAI model 150, parameters of GAI model 150 are adjusted to encode learned information. Initial training of GAI model 150 is generally performed on a base model. A base model may be licensed and hosted by a third party, purchased, or acquired as an open-source model. The base model may have been pre-trained on a vast amount of data. In general, however, a base model is not specifically trained to perform industrial design functions. The initial training in step 401 fine-tunes GAI model 150 to perform industrial design tasks. The initial training in step 401 may be an unsupervised learning process, including providing the base model with static data including industrial product literature, industry standard data, data about standard configurations for industrial units, existing base designs from base design repository 140, safety requirements in various countries, and other data relevant to the industrial systems.

Step 403 of method 400 is performing industry preference training for GAI model 150. Step 403 may be performed by GAI Update Module 340 of FIG. 3. Industry preference training is performed by providing GAI model 150 with feedback, where the feedback includes user selections within industrial design application 120 and finalized industrial designs submitted by users in industrial design application 120. This feedback is provided to GAI model 150 continuously over time, such that GAI model 150 stays up to date with changing industry preferences in various industries.

Step 405 of method 400 is initiating a base design update for a generic base design, for example a generic base design stored in base design repository 140. Step 405 may be performed by Design Update Module 313 of FIG. 3. As discussed with respect to Design Update Module 313 above, the base design update may be initiated for a generic base design when a pre-determined time-period has elapsed since the previous update of that generic base design. Alternatively, a generic base design may be updated when an administrator such as an engineer specifically requests for that base design to be updated or when the generic base design has been provided to users above a threshold number of times.

Step 407 of method 400 is generating a prompt for GAI model 150. Step 407 may be performed by Prompt Generation Module 335 of FIG. 3. The prompt may be generated based on a prompt template, such as prompt template 910 of FIG. 9. The prompt may include the metadata of the generic base design (see, e.g., metadata 220 of FIG. 2) and a request to update the base design based on common industry preferences. The prompt may also differ depending on whether the generic base design to be updated is in open design library 370 of FIG. 3, or Company Design Library 375 of FIG. 3. As such, the generating of the prompt in step 407 may include tailoring the prompt based on the library the generic base design is stored in. The generation of the prompt using prompt template 910 is discussed further in FIG. 9 below. The prompt may also include the relevant industries and install locations associated with the generic base design, since common selections may vary depending on the industry and location.

Step 409 of method 400 is submitting the prompt (i.e., the prompt generated in step 407) to GAI model 150. Step 409 may be performed by GAI Interface Module 345 of FIG. 3.

Step 411 of method 400 is receiving an updated base design from GAI model 150. Step 411 may be performed by GAI Interface Module 345 of FIG. 3. The updated base design may include updated metadata for the generic base design generated by GAI model 150. GAI model 150 updates the metadata based on learned common selections for the industry and install location. GAI model 150 may continually learn the common selections over time. GAI model 150 is provided with finalized industrial designs submitted by users in industrial design application 120 to learn selections that are popular among many users. GAI model 150 may also be updated with other industrial information, such as external industrial designs, new industrial specifications, and new regulations and standards. As such, the updated base design generated by GAI model 150 is aligned with common industry standards and preferences learned by GAI model 150 from various sources.

It is noted that GAI model 150 may only generate updated base designs with new configurations that are popular among users across multiple organizations. As such, GAI model 150 may be trained to recognize if preferences are particular to a specific organization. If a preference is organization-specific, GAI model 150 will only incorporate the preference into a company-specific base design. For example, if a preference generally only used by users affiliated with Company 1, GAI model 150 will only incorporate the generic base design into a generic base design in Company 1 Design library 375a of FIG. 3. A preference will not be incorporated into a generic base design in Open Design Library 370 unless the preference is applicable to users in multiple different organizations. GAI model 150 may be trained to recognize when a preference is either widespread or company specific. Several factors may play a role in this consideration, including the numbers of users in various organizations that have made selections aligning with the preference, the industries in which the selections are made, and the frequency of the selections. In some embodiments, GAI model 150 may be trained to recognize that users from a threshold number of organizations have made certain selections. If the number of organizations utilizing the selection exceeds the threshold, GAI model 150 may apply the selection to update a design in open design library 370. In other embodiments, GAI model 150 may be trained to recognize that a selection is made outside of a specific organization above a threshold percentage of the total times the selection is made. If the percentage exceeds the threshold, GAI model 150 may apply the selection to a generic design in open design library 370. In general, if GAI model 150 determines that a preference is widespread across multiple organizations, the preference may be incorporated by GAI model 150 into updated base designs for open design library 370 of FIG. 3.

Various metadata (e.g. metadata 220 of FIG. 2) of the generic base design may be updated by GAI model 150 to align with common selections among users of industrial design application 120. For example, GAI model 150 may update Components 220h to include components (such as models of motor controllers, the type of circuit breakers, the type of mounting station, etc.) to align with components that are selected often by the users. Option Packs 220j may also be updated, for example to include different default selections, additional options, or removed options. Various other metadata 220 may also be updated to align with common selections, including attributes 220i, model artifacts 220g, and related industries 220f.

Step 413 of method 400 is sending the updated base design to an administrator for review. Step 413 may be performed by U/I Module 310 of FIG. 3. The updated base design may be sent, for example, to Admin Device 112 of FIG. 1. The administrator may be an engineer who reviews the updated base design to ensure that the updated base design is in accordance with industry standards and applicable laws and regulations. The administrator may either approve the updated base design for inclusion in base design repository 140 or reject the base design.

Step 415 of method 400 is receiving approval for the base designs. Step 415 may be performed by U/I Module 310. Industrial design application 120 receives the administrator approval once the administrator approves of the base design in Step 413.

Step 417 of method 400 is updating the generic base design in the base design repository 140. Step 417 may be performed by Design Update Module 313. Industrial design application 120 updates the generic base design if the administrator approval is received in Step 415. Updating the generic base design may include adding the updated base design to base design repository 140. In some embodiments, the original generic base design provided to GAI model 150 may be kept in base design repository 140 until an administrator reviews it and determines to either remove it or keep it. Accordingly, once the updated base design is added to base design repository 140, industrial design application 120 may prompt the administrator to review the original base design.

It is noted that if the administrator rejects the updated base design in Step 413, industrial design application 120 receives the rejection and will not add the updated base design to base design repository 140. Instead, industrial design application 120 may provide an indication of rejection to GAI model 150 as feedback.

Step 419 of method 40 is receiving a request from a user for a design of an industrial automation project. Step 419 may be performed by U/I Module 310. The user creates the request on a user interface of a user device such as user device 110a in FIG. 1. The request may include parameters of an industrial system the user wishes to design. In the example of an MCC, the request includes a motor-load list, as well as the industry and the installation location of the MCC. The user may input the parameters of the industrial automation project in a user interface, for example the user interface 800 of FIG. 8A.

Step 421 of method 400 is providing the updated base design to the user. Step 421 may be performed by U/I Module 310. The updated base design may be included an initial layout of the design for the industrial automation project provided to the user in response to the design request in step 619. The initial layout may be displayed to the user via a user interface, for example the user interface 800 of FIG. 8B.

Step 423 of the method 400 is receiving the user's submission of a finalized design of the industrial automation project. Step 423 may be performed by U/I Module 310. Once the user has made all desired selections and arrived at the final design, the user may submit the finalized design of the industrial automation project. The submission may include, for example, a request for a quote.

Step 425 of method 400 is providing the finalized design to GAI model 150 as feedback for updating the learned common industrial design selections of GAI model 150. Step 425 may be performed by GAI Update Module 340. Since designs may be submitted by many users across various industries, providing this feedback allows GAI model 150 to stay updated with industry trends.

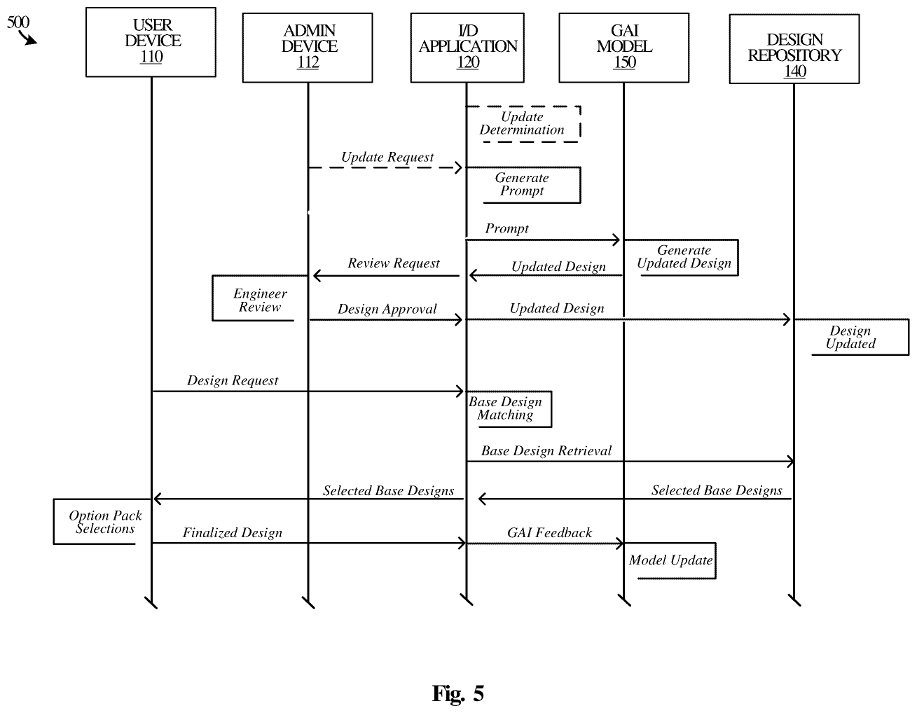

FIG. 5 illustrates an operational scenario performed according to some embodiments. Operational scenario 700 includes user device 110, industrial design application 120, base design repository 140, and GAI model 150.

The operational scenario may begin in two different ways, as indicated by the dotted lines in FIG. 5. In one scenario, an administrator on admin device 112 may submit an update request to industrial design application 120 (for example, via U/I Module 310 of FIG. 3). The update request may be a request to update a specific generic base design in base design repository 140. In another scenario, industrial design application 120 makes an update determination, which is a determination that a trigger has been satisfied for updating a specific generic base design in base design repository 140. The update determination may be made, for example, by Design Update Module 313 of FIG. 3. The update determination may be made, for example, by determining that a pre-determined time period has elapsed since the last update or a determination that the generic base design has been provided to users above a threshold number of times, as discussed in FIG. 3 above. Once either the request is received or the determination is made, industrial design application 120 generates a prompt for GAI model 150. The prompt generation may be performed by Prompt Generation Module 335 of FIG. 3. The prompt may include some or all the metadata for the generic base design (e.g., metadata 220 of FIG. 2) and a request to update the generic base design based on common configurations. The prompt may be generated based on a prompt template, such as prompt template 910 of FIG. 9. Industrial design application 120 then submits the prompt to GAI model 150, for example via GAI Interface Module 345 of FIG. 3. In response, GAI model 150 generates a response, the response including updated metadata for the generic base design. GAI model 150 provides the updated metadata to industrial design application 120 (for example, via GAI Interface Module 345 of FIG. 3). Industrial design application 120 then sends the updated metadata of the generic base design to admin device 112 for review (e.g., via U/I Module 310 of FIG. 3). An administrator on admin device 112 reviews the updated base design. The administrator (such as an engineer) may check the updated base design for quality, conformity with standards and regulations, and for any potential issues related to adding the updated base design to base design repository 140. If the administrator approves the updated base design, the administrator submits the approval to the industrial design application 120 (for example, via the U/I Module 310 of FIG. 3). Industrial design application 120 then adds the updated base design to base design repository 140, including replacing the metadata of the original generic base design with the updated metadata. Adding the updated base design to base design repository 140 may be performed, for example, by Design Update Module 313.

Subsequently in operational scenario 500, a user may submit a design request for a design of an industrial automation project, including parameters for the project as shown for example in user interface 800 of FIG. 8A. In response to receiving the design request (for example, via U/I Module 310 of FIG. 3), industrial design application 120 performs a base design matching operation based on the design request. Specifically, in the base design matching operation, generic base designs are selected based on the parameters provided in the request. In the example of MCC design, the base design matching operation may select a generic base design for a VFD based on the rating, the industry, and the installation location selected by the user. Industrial design application 120 retrieves the selected generic base designs from base design repository 140, and base design repository 140 returns the selected generic base designs, which may include the updated base design. Industrial design application 120 provides the generic base designs to the user on user device 110 (for example, via U/I Module 310 of FIG. 3). The user may make various selections within the option packs, as shown for example in FIG. 8D. Once the user is satisfied with the layout of the industrial design, the user may submit a finalized design of the layout via a user interface of user device 110. Such a submission may include, for example, submitting the industrial design for a quote. When industrial design application 120 receives the submission of the finalized design (for example, via U/I Module 310 of FIG. 3), industrial design application 120 provides the finalized design to GAI model 150 as feedback (for example, via GAI Interface Module 345 of FIG. 3). GAI model 150, upon receiving the feedback, updates its learned knowledge common selection among various users.

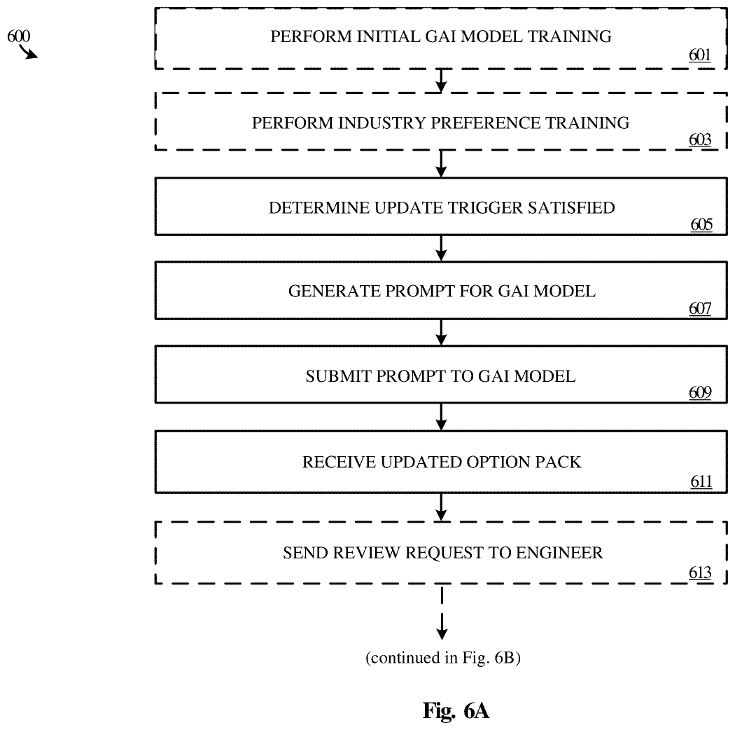

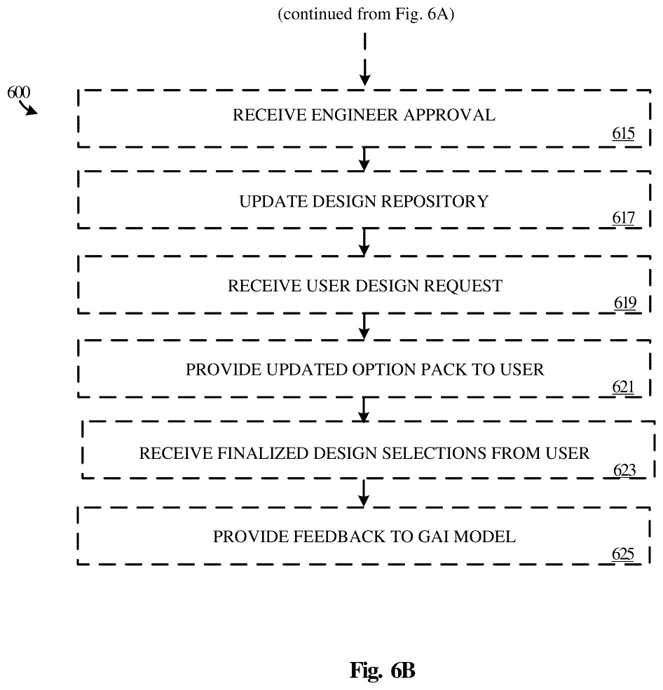

FIGS. 6A and 6B illustrate computer-implemented method 600 for updating option packs performed according to some embodiments.

Step 601 of method 600 is performing initial GAI model training. Step 601 may be performed by GAI Update Module 340 of FIG. 3. In training GAI model 150, parameters of GAI model 150 are adjusted to encode learned information. Initial training of GAI model 150 is generally performed on a base model. A base model may be licensed and hosted by a third party, purchased, or acquired as an open-source model. The base model may have been pre-trained on a vast amount of data. In general, however, a base model is not specifically trained to perform industrial design functions. The initial training in step 601 fine-tunes GAI model 150 to perform industrial design tasks. The initial training in step 601 may be an unsupervised learning process, including providing the base model with industrial product literature, industry standard data, data about standard configurations for industrial units, safety requirements in various countries, and other data relevant to the industrial systems.

Step 603 of method 600 is performing industry preference training for the GAI model 150. Step 603 may be performed by GAI Update Module 340 of FIG. 3. Industry preference training is performed by providing GAI model 150 with feedback, where the feedback includes user selections within industrial design application 120 and finalized industrial designs submitted by users in industrial design application 120. This feedback is provided to GAI model 150 continuously over time, such that GAI model 150 stays up to date with changing industry preferences in various industries.

Step 605 of method 600 is initiating an option pack update for an option pack of generic base design (e.g., option pack 220j of a base design 200 in FIG. 2). Step 605 may be performed by Design Update Module 313 of FIG. 3. The option pack update may be initiated for a generic base design when a pre-determined time-period has elapsed since the previous update of that generic base design. Alternatively, an option pack may be updated when an administrator such as an engineer specifically requests for that option pack to be updated, or when the generic base design has been provided to users above a threshold number of times.

Step 607 of method 600 is generating a prompt for the GAI model 150. Step 607 may be performed by Prompt Generation Module 335 of FIG. 3. The prompt may be generated based on a prompt template, such as prompt template 920 of FIG. 9. The prompt may include the metadata of the generic base design (see, e.g. metadata 220 of FIG. 2) including option packs 220j metadata, and a request to update the option pack of the generic base design based on common selections among users. The prompt may also differ depending on whether the generic base design to be updated is in open design library 370 of FIG. 3, or Company Design Library 375 of FIG. 3. As such the generating of the prompt in step 607 may include tailoring the prompt based on the library the generic base design is stored in. The generation of the prompt using prompt template 910 is discussed further in FIG. 9 below.

Step 609 of method 600 is submitting the prompt (i.e., the prompt generated in step 607) to GAI model 150. Step 609 may be performed by GAI Interface Module 345 of FIG. 3.

Step 611 of method 600 is receiving an updated option pack from GAI model 150.

Step 611 may be performed by GAI Interface Module 345 of FIG. 3. GAI model 150 generates the updated base design based on learned common configurations in the industry. The updated option pack may include one or more of a different default selection, a removed option, or an additional option compared to the initial option pack. For example, while the initial option pack may have a thermal circuit breaker as the default selection for a circuit breaker option pack in a VFD, the updated option pack may have a thermal-magnetic circuit breaker as a default selection, due to a learned preference that the thermal-magnetic circuit breaker has become more popular. In another example, the initial option pack may have included a selectable option to have “No Circuit Breaker” in the VFD. The updated option pack may have removed the “No Circuit Breaker,” based on learned knowledge that users almost never select the “No Circuit Breaker Option.” In yet another example, the initial option pack might not have a magnetic circuit breaker option in the option pack. The updated option pack may include a magnetic circuit breaker based on learned knowledge of GAI model 150 that this option is commonly selected in similar units. Furthermore, GAI model 150 may distinguish between company specific preferences and widespread preferences when updating option packs, as discussed in step 411 of method 400 above.

Step 613 of method 600 is sending the generic base design with the updated option pack to an administrator for review. Step 413 may be performed by U/I Module 310 of FIG. 3. The updated base option pack may be sent, for example, to Admin Device 112 of FIG. 1. The administrator may be an engineer who reviews the updated base design to ensure that the updated base design is in accordance with industry standards and applicable laws and regulations. The administrator may either approve the updated base design for inclusion in base design repository 140 or reject the base design.

Step 615 of method 600 is receiving approval for the updated option pack. Step 615 may be performed by U/I Module 310. Step 615 occurs when the administrator, after reviewing the option pack, indicates approval of the updated option pack provided in step 613.

Step 617 of method 600 is updating base design repository 140. Step 617 may be performed by Design Update Module 313. Specifically, in step 617, industrial design application 120 replaces the initial option pack of the generic base design with the updated option pack of the generic base design approved by the engineer.

It is noted that if the administrator rejects the updated base design in step 613, industrial design application 120 receives the rejection and will not add the updated base design to base design repository 140. Instead, an indication that the administrator rejected the base design may be provided to GAI model 150 as feedback.

Step 619 of method 600 is receiving a request from a user for a design of an industrial automation project. Step 619 may be performed by U/I Module 310. The user creates the request on a user interface of a user device such as user device 110a in FIG. 1. The request may include parameters of an industrial system the user wishes to design. In the example of an MCC, the request includes a motor-load list, as well as the industry and the installation location of the MCC. The user may input the parameters of the industrial automation project in a user interface, for example user interface 800 of FIG. 8A.

Step 621 of method 600 is providing the updated option pack to the user. Step 621 may be performed by U/I Module 310. The updated option pack may be included in the generic base design selected for an initial layout of the design for the industrial automation project provided to the user in response to the design request in step 619. The initial layout may be displayed to the user via a user interface, for example user interface 800 of FIG. 8B.

Step 623 of the method 600 is receiving the user's submission of a finalized design of the industrial automation project. Step 623 may be performed by U/I Module 310. Once the user has made all desired selections and arrived at the final design, the user may submit the finalized design of the industrial automation project. The submission may include, for example, a request for a quote.

Step 625 of the method 600 is providing the finalized design to GAI model 150 as feedback for updating the learned common industrial design selections of GAI model 150. Step 625 may be performed by GAI Update Module 340. Since designs may be submitted by many users across various industries, providing this feedback allows GAI model 150 to stay updated with industry trends.

FIG. 7 illustrates an operational scenario performed according to some embodiments. Operational scenario 700 includes user device 110, industrial design application 120, base design repository 140, and GAI model 150.

The operational scenario may begin in two different ways, as indicated by the dotted lines in FIG. 7. In one scenario, an administrator on admin device 112 may send an update request to industrial design application 120 (for example, via U/I Module 310 of FIG. 3). The update request may be a request to update a specific option pack of a generic base design in base design repository 140. The update determination may be made, for example, by Design Update Module 313 of FIG. 3. In another scenario, industrial design application 120 makes an update determination, which is a determination to update a specific generic base design in base design repository 140. The update determination may be made, for example, by determining that a pre-determined time period has elapsed since the last update or a determination that the generic base design has been provided to users above a threshold number of times, as discussed in FIG. 3 above. Once either the request is received or the determination is made, industrial design application 120 generates a prompt for the GAI model 150. The prompt generation may be performed by Prompt Generation Module 335 of FIG. 3. The prompt may include the metadata of the option pack (e.g., option packs 220j metadata of FIG. 3) generic base design and a request to update the option pack base design based on common selections and may be generated based on a prompt template such as prompt template 910 of FIG. 9. Industrial design application 120 then submits the prompt to GAI model 150, for example via GAI Interface Module 345 of FIG. 3. GAI model 150 generates a response, the response including an updated option pack. Once the updated option pack is generated, it is provided by GAI model 150 to industrial design application 120 (for example, via GAI Interface Module 345 of FIG. 3). Industrial design application 120 then sends the updated option pack to admin device 112 for review (for example via U/I Module of FIG. 3). An administrator on admin device 112 reviews the updated base design. The administrator (such as an engineer) may check the updated option pack for quality, conformity with standards and regulations, and for any potential issues related to adding the updated base design to base design repository 140. If the administrator approves the updated option pack, the administrator submits the approval to industrial design application 120 (for example via U/I Module 310). Industrial design application 120 then adds the updated base design to base design repository 140, including replacing the option pack of the generic base design with the updated option pack. Adding the updated option pack to base design repository 140 may be performed, for example, by Design Update Module 313.

Subsequently in operational scenario 700, a user may submit a design request for a design of an industrial automation project, including parameters for the project as shown for example in user interface 800 of FIG. 8A. In response to receiving the design request (e.g., via U/I Module 310 of FIG. 3), industrial design application 120 performs a base design matching operation based on the design request. Specifically, in the base design matching operation, generic base designs are selected based on the parameters provided in the request. In the example of MCC design, the base design matching operation may select a generic base design for a VFD based on the rating, the industry, and the installation location selected by the user. Industrial design application 120 retrieves the selected generic base designs from base design repository 140, and base design repository 140 returns the selected generic base designs, which may include the generic base design with the updated option pack. Industrial design application 120 provides generic base designs to the user on user device 110 (for example, via U/I Module 310 of FIG. 3). The user may make various selections within the option packs, as shown for example in FIG. 8D. Once the user is satisfied with the layout of the industrial design, the user may submit a finalized design of the layout via a user interface of user device 110. Such a submission may include, for example, submitting the industrial design for a quote. When industrial design application 120 receives the submission of the finalized design (for example, via U/I Module 310 of FIG. 3), industrial design application 120 provides the finalized design to GAI model 150 as feedback (for example, via GAI Interface Module 345 of FIG. 3). GAI model 150, upon receiving the feedback, updates its learned knowledge common selection among various users.

FIGS. 8A-8D show four different screens of user display 800 in industrial design application 120 according to some embodiments. User display 800 is displayed to a user on a user device (e.g., user devices 110a, 110b, 110n of FIG. 1) via U/I Module 310 of FIG. 3. User display 800 may be viewed in an internet browser in a separate application on the user device. User display 800 shows an example of a design for an MCC. However, it is noted that other embodiments of the present technology may include requests for designs of other industrial systems and components.

FIG. 8A illustrates a screen user interface 800 in which a user may create a request for a design of an industrial automation project (in this case, an MCC). User interface 800 shows a display in which a user may create a request for a design of an industrial automation project (in this case, an MCC). In Product Selection field 805, the user selects a desired product. In this case, a user has elected to request a design for a “CENTERLINE IEC Motor Control Center.” In the Project Details Field 810, the user enters parameters for the industrial system to be designed. The Project Details Field 810 includes a “Project Name,” a “Configuration Name,” a “Sold to Location,” an “Installation Location,” and the “Industry.” The illustrated project details in Project Details Field 810 are exemplary only. In addition to the project details, the user creates motor-load list 815. The motor-load list includes the controllers a user needs in the MCC, where each controller may be used to drive a certain component in the industrial environment (e.g., pumps, belts, and mixers). For each motor load, the user indicates the name of the MCC, the Load Name, the type of controller, the rating for the controller, the Rating Unit, and the Full Load Amps (where some fields may not be included depending on the component requested). Clickable fields 820 allow a user to add a new load (i.e., motor controller) to the list, copy selected loads, or delete selected loads. When a user is satisfied with the parameters, the user may click the “View Selected Configuration” button 825. Clicking this button is the request for a design of an industrial automation project, as discussed, for example, in step 419 of the method 400 and step 619 of method 600.

FIG. 8B illustrates another screen in user interface 800 in which the user has received an initial industrial automation project design from the industrial design application (e.g., industrial design application 120 in FIG. 1). User interface 800 of FIG. 8B shows a display of an initial design for an industrial automation project from the industrial design application (such as the industrial design application 120 in FIG. 1). The initial design may be generated based on the parameters input by the user in user interface 800 of FIG. 8A. The initial design may include user-specific customizations, as discussed in greater detail in related applications incorporated by reference above. Field 830 displays basic information about the generated design, including the name of the design, the name of the configuration, the Line Voltage, the Control Voltage, and an estimated price for the configuration. Field 835 displays MCCs included in the design. In this example, the user has requested only one MCC in the design; however, users may be able to request a design including multiple MCCs. Design Layout Field 840 shows a broad view of the layout of the design of the industrial automation project. The layout in Design Layout field 840 shows an arrangement of all the industrial units (industrial units 210) to be included in the MCC. For example, the layout may include a motor controller for each motor controller requested motor-load list 815 of FIG. 8A. The initial design may include the updated base design, as discussed in step 421 of method 400, or the updated option pack, as discussed in step 621 of method 600.

The view in FIG. 8B shows high-level information about each customized base design, where each customized base design represents an industrial unit (industrial unit 210) such as a motor controller. For example, the bottom unit in the second column of the MCC design in FIG. 8B is an SMC (Smart Motor Controller). “2Q” indicates the location of the SMC in the generated layout (i.e., position Q of the second column.” “Unit 2” indicates the name provided by the user in FIG. 8A. The power and amperage of the SMC is also displayed. A user may select any industrial unit in design layout field 840 to view further details about the configuration of the selected industrial unit, as discussed in relation to FIG. 8C below. The user may click Generate Field 845 to request alternate graphical representations of the MCC (such as a schematic electrical view or a top-down view).

FIG. 8C illustrates another screen of user interface 800 that is displayed when the user selects an industrial unit from the layout in FIG. 8B. In the example of FIG. 8C, the user has selected “Unit 2” (the SMC). The selection of the component by the user causes Unit Window 870 to be overlayed in user interface 800. Configuration list 865 shows details of how the SMC is configured. Configuration list 865 represents multiple configurable attribute selections in the customized base design generated by the GAI model 150. For example, the customized base design includes a Mounting Type of “Withdrawable,” which may be based on a learned user-preference of GAI model 150 that a specific user generally prefers withdrawable mounting for SMCs. The user has the option of swapping the design of the SMC for alternative design 860, which may be additional customized base designs generated by GAI model 150. Alternatively, alternative designs 860 may be generic base designs selected from the base design repository (such as base design repository 140 in FIG. 1). A user also has the option of editing the details of the design of the unit (the SMC) provided by clicking “Edit Unit Details” button 855. The SMC represented in Unit Window 870 may be an updated base design received by industrial design application 120 (for example, in step 411 of method 400).

FIG. 8D illustrates another screen of user interface 800 that is displayed after a user has selected Edit Unit Details Button 855 of FIG. 8C. Specifically, upon the user request to edit the unit details, Unit Configuration Window 875 appears on screen. Unit Configuration Window 875 includes option packs 880 of the unit the user requested to edit. Each option pack 880 includes selectable options 885 which are selectable by the user to configure the unit. The user may edit the configuration of the unit by selecting one of option packs 880 and making a selection of one of selectable options 885. In this case, the user has selected “Operator Station.” The user may then select one of selectable options 885. This allows the user to deviate from the customized base design provided by GAI model 150. Option packs 880 may be option packs 220j of FIG. 2.

As an example, a generic base design (in base design repository 140 of FIG. 1) may include an operator station option pack 880 including a 3-Position Switch, three indicator lights (G, Red, and Amber) and a HIM (see the top-left selectable option of the selectable options 885). However, GAI model 150 may have learned based on past usage that the user requesting the design usually wants only a HIM (which may be, for example, for cost saving purposes). As such, the customized base design generated by GAI model 150 may include “With HIM” as an operator station (the third option on the right). Such a customized base design may be generated as discussed in greater detail in related applications incorporated by reference above. In the present design, the user does not require an operator station for a particular SMC; thus, the user has deviated from the customized base design by selecting “Without Operator Station” on the top right. The industrial design selection “Without Operator Station” is received by the industrial design application 120. The one or more of option packs 880 may be an updated option pack received by industrial design application 120 (for example, in step 611 of method 600).

Once the user has made all modifications in user interfaces 800 (for example in the displays shown in FIGS. 8C and 8D above) the user may submit a finalized design of the industrial automation project, as discussed for example in step 423 of method 400 and step 623 of method 600.

FIG. 9 illustrates prompt templates 910, 920 according to some embodiments. Prompt templates 910, 920 are files stored in industrial design application 120. Prompt templates 910, 920 include a combination of text and placeholders, where the placeholders are replaced with the relevant data during prompt generation as discussed below. It is noted that in some embodiments prompt templates 910, 920 may include additional or fewer placeholders. Prompt templates 910, 920 may be utilized, for example, by Prompt Generation Module 335 of FIG. 3 to generate prompts for GAI model 150.

Prompt template 910 may be used for requesting updates of generic base designs as set forth in method 400 and operational scenario 500 discussed above. Prompt template 910 includes multiple placeholders that are filled in with appropriate data to generate the prompt. The placeholders in prompt template 910 include<Base Design Metadata>, <Industries> and <Locations>. During prompt generation, the placeholder <Base Design Metadata> is replaced with information about the generic base design, such as the generic base design selected from base design repository 140 of FIG. 1. This may include, for example, some or all metadata 220 of FIG. 2. The <Industries>placeholder is filled in with the applicable industries for the generic base design. The <Install Locations>placeholder is filled in with the countries in which the generic base design is used. This field is used as contextual information since design preferences may vary among various industries.

The request to update the base design in prompt template 910 includes the placeholder: < “Based on common preferences specific to [Company X]” or “Based on common user preferences across multiple organizations.”>This generated prompt will select the text string from this placeholder depending on which design library from the base design repository 140 the generic base design is stored in. For example, if the generic base design is in the Company 1 Design Library 375a, the placeholder will be filled in with: “Based on common preferences specific to Company 1.” Alternatively, if the generic base design is stored in the open design library 370, the placeholder will be filled in with: “Based on common user preferences across multiple organizations.” This tailoring of the prompt allows GAI model 150 to tailor generic base designs for specific companies without using company specific design information for users outside of the organization. If the generic base design is in Open Design Library 370, the prompt indicates to GAI model 150 that the generic base design is to be updated based on common user preferences across multiple organizations. As such, generic base designs in Open Design Library 370 will not be updated based on preferences specific to an organization. This arrangement facilitates the protection of company specific design information and intellectual property.

Prompt template 920 may be used for requesting updates of option packs generic base designs as set forth in method 600 and the operational scenario 700 discussed above. Prompt template 920 includes multiple placeholders that are filled in with appropriate data to generate the prompt. The placeholders in prompt template 920 include<Base Design Metadata>, <Industries>, <Locations>, and <Option Pack Metadata>. During prompt generation, the placeholder <Base Design Metadata> is replaced with information about the generic base design, such as the generic base design selected from base design repository 140 of FIG. 1. This may include, for example, some or all metadata 220 of FIG. 2. The <Industries>placeholder is filled in with the applicable industries for the generic base design. The <Install Locations>placeholder is filled in with the countries in which the generic base design is used. The <Option Pack Metadata>placeholder is filled in with option pack metadata (e.g., option pack 220j metadata of FIG. 2) retrieved from base design repository 140.

Prompt template 920 includes the placeholder: < “Based on common preferences specific to [Company X]” or “Based on common user preferences across multiple organizations.”>This generated prompt will select the text string from this placeholder depending on which design library from base design repository 140 the generic base design is stored in. For example, if the generic base design is in Company 1 Design Library 375a, the placeholder will be filled in with: “Based on common preferences specific to Company 1.” Alternatively, if the generic base design is stored in open design library 370, the placeholder will be filled in with: “Based on common user preferences across multiple organizations.” This tailoring of the prompt allows GAI model 150 to tailor generic base designs for specific companies without using company specific design information for users outside of the organization. If the generic base design is in Open Design Library 370, the prompt indicates to GAI model 150 that the generic base design is to be updated based on common user preferences across multiple organizations. As such, generic base designs in Open Design Library 370 will not be updated based on preferences specific to an organization. This arrangement facilitates the protection of company specific design information and intellectual property.

Prompts generated from prompt template 910, 920 are submitted to GAI model 150. It is noted that prompt templates 910, 920 are representative. Other embodiments may include different request language, and may include additional placeholders, or fewer placeholders.

FIG. 10 illustrates computing device 1001 that is representative of any system or collection of systems in which the various processes, programs, services, and scenarios disclosed herein may be implemented. Examples of computing device 1001 include, but are not limited to, desktop and laptop computers, tablet computers, mobile computers, and wearable devices. Examples may also include server computers, web servers, cloud computing platforms, and data center equipment, as well as any other type of physical or virtual server machine, container, and any variation or combination thereof.

Computing device 1001 may be implemented as a single apparatus, system, or device or may be implemented in a distributed manner as multiple apparatuses, systems, or devices. Computing device 1001 includes, but is not limited to, processing system 1002, a storage system 1003, software 1005, communication interface system 1007, and user interface system 1009. Processing system 1002 is operatively coupled with storage system 1003, communication interface system 1007, and user interface system 1009.

Processing system 1002 loads and executes software 1005 from storage system 1003. Software 1005 includes and implements industrial design application 120, which is representative of the application service processes discussed with respect to the preceding figures, such as method 400 of FIGS. 4 and method 600 of FIGS. 6A and 6B. When executed by processing system 1002, software 1005 directs processing system 1002 to operate as described herein for at least the various processes, operational scenarios, and sequences discussed in the foregoing implementations. Computing device 1001 may optionally include additional devices, features, or functionality not discussed for purposes of brevity.

Referring still to FIG. 10, processing system 1002 may comprise a microprocessor and other circuitry that retrieves and executes software 1005 from storage system 1003. Processing system 1002 may be implemented within a single processing device but may also be distributed across multiple processing devices or sub-systems that cooperate in executing program instructions. Examples of processing system 1002 include general purpose central processing units, graphical processing units, application specific processors, and logic devices, as well as any other type of processing device, combinations, or variations thereof.

Storage system 1003 may comprise any computer-readable storage media device readable by processing system 1002 and capable of storing software 1005. Storage system 1003 may include volatile and nonvolatile, removable, and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated or transitory signal.

In addition to computer readable storage media, in some implementations storage system 1003 may also include computer readable communication media over which at least some of software 1005 may be communicated internally or externally. Storage system 1003 may be implemented as a single storage device but may also be implemented across multiple storage devices or sub-systems co-located or distributed relative to each other. Storage system 1003 may comprise additional elements, such as a controller, capable of communicating with processing system 1002 or possibly other systems.

Software 1005 (including industrial design application 120) may be implemented in software instructions and among other functions may, when executed by processing system 1002, direct processing system 1002 to operate as described with respect to the various operational scenarios, sequences, and processes illustrated herein. For example, software 1005 may include program instructions for implementing an application service process as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. The software 1005 may include additional processes, programs, or components, such as operating system software, virtualization software, or other application software. The software 1005 may also comprise firmware or some other form of machine-readable processing instructions executable by the processing system 1002.

In general, software 1005 may, when loaded into processing system 1002 and executed, transform a suitable apparatus, system, or device (of which computing device 1001 is representative) overall from a general-purpose computing system into a special-purpose computing system customized to support an application service in an optimized manner. Indeed, encoding software 1005 on storage system 1003 may transform the physical structure of storage system 1003. The specific transformation of the physical structure may depend on various factors in different implementations of this description. Examples of such factors may include, but are not limited to, the technology used to implement the storage media of storage system 1003 and whether the computer-storage media are characterized as primary or secondary storage, as well as other factors.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. The software 1005 may include additional processes, programs, or components, such as operating system software, virtualization software, or other application software. Software 1005 may also comprise firmware or some other form of machine-readable processing instructions executable by processing system 1002.

In general, software 1005 may, when loaded into processing system 1002 and executed, transform a suitable apparatus, system, or device (of which computing device 1001 is representative) overall from a general-purpose computing system into a special-purpose computing system customized to support an application service in an optimized manner. Indeed, encoding software 1005 on storage system 1003 may transform the physical structure of storage system 1003. The specific transformation of the physical structure may depend on various factors in different implementations of this description. Examples of such factors may include, but are not limited to, the technology used to implement the storage media of storage system 1003 and whether the computer-storage media are characterized as primary or secondary storage, as well as other factors.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel, or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112 (f) will begin with the words “means for”, but use of the term “for” in any other context is not intended to invoke treatment under 35 U.S.C. § 112 (f). Accordingly, the applicant reserves the right to pursue additional claims after filing this application to pursue such additional claim forms, in either this application or in a continuing application.

The phrases “in some embodiments,” “according to some embodiments,” “in the embodiments shown,” “in other embodiments,” and the like generally mean the particular feature, structure, or characteristic following the phrase is included in at least one implementation of the present technology and may be included in more than one implementation. In addition, such phrases do not necessarily refer to the same embodiments or different embodiments.

What is claimed is:

1. A computer-implemented method for updating a generic base design, the method comprising:
determining that a trigger for updating the generic base design of an industrial unit has been satisfied, wherein:
the generic base design is one of a plurality of generic base designs stored in a base design repository, and
the generic base design comprises metadata defining the industrial unit;
generating, in response to determining that the trigger has been satisfied, a prompt to elicit a response from a Generative Artificial Intelligence (GAI) model trained on data including previous industrial design submissions from a plurality of users of an industrial design application, wherein the prompt comprises:
the metadata of the generic base design, and
a request to update the generic base design based on the previous industrial design submissions;
submitting the prompt to the GAI model; and
receiving, from the GAI model in response to the prompt, an updated base design comprising one or more differences from the generic base design, wherein the differences are representative of previous selections made in the previous industrial design submissions from the plurality of users of the industrial design application.

2. The computer-implemented method of claim 1, wherein the determining that the trigger has been satisfied comprises one of:
receiving, from an administrator of the industrial design application, a request to update the generic base design,
determining that a pre-determined time-period has elapsed since a last update of the generic base design, and
determining that the generic base design has been selected for initial designs provided to users above a threshold number of times.

3. The computer-implemented method of claim 1, further comprising:
sending to an administrator of the industrial design application, in response to receiving the updated generic base design, a request to review the updated base design; and
receiving, from the administrator in response to the request, an approval of the updated base design.

4. The computer-implemented method of claim 3, further comprising:
replacing, in response to receiving the approval, the generic base design with the updated base design.

5. The computer-implemented method of claim 1, further comprising:
receiving a request from a user of the industrial design application for a design for an industrial automation project; and
sending to the user, in response to the request for a design, an initial layout of the industrial automation project, the initial layout including the updated base design.

6. The computer-implemented method of claim 5, further comprising:
receiving, from the user, a submission of a finalized layout of the industrial automation project, the finalized layout comprising one or more modifications of the initial layout; and
providing the finalized layout to the GAI model for updating learned common selections among users of the industrial design application.

7. The computer-implemented method of claim 1, further comprising:
providing the GAI model with static data during initial training, the static data comprising one or more of: industrial product literature, industry standard data, and safety requirements data.

8. The computer-implemented method of claim 1, wherein:
the generic base design comprises an initial option pack;
the initial option pack comprising a plurality of options selectable by users of an industrial design application to configure an aspect of the industrial unit;
the initial option pack further comprising a default selection of one of the plurality of options;
the updated generic base design comprises an updated option pack; and
the one or more differences comprise one or more differences between the initial option pack and the updated option pack.

9. The computer-implemented method of claim 8, wherein the one or more differences between the updated option pack and the initial option pack comprise one or more of:
a different default selection in the updated option pack compared to the initial option pack;
a new option of the plurality of options in the updated option pack compared to the initial option pack; and
a removed option of the plurality of options in the updated option pack compared to the initial option pack.

10. The computer-implemented method of claim 1, wherein the generating the prompt further comprises:
determining whether the generic base design is from an open design library or one of a plurality of company design libraries, wherein:
the open design library comprises a plurality of generic base designs available to all users of the industrial design application, and
each of the plurality of company design libraries comprises one or more generic base designs available only to users affiliated with a specific company; and
tailoring the prompt depending on the determining whether the generic base design is from an open design library or one of the plurality of company design libraries.

11. A system for updating a generic base design, the system comprising:
one or more processors; and
one or more memories operably coupled to the one or more processors and having stored thereon software instructions that, upon execution by the one or more processors, cause the one or more processors to:
determine that a trigger for updating the generic base design of an industrial unit has been satisfied, wherein:
the generic base design is one of a plurality of generic base designs stored in a base design repository, and
the generic base design comprises metadata defining the industrial unit;
generate, in response to determining that the trigger has been satisfied, a prompt to elicit a response from a Generative Artificial Intelligence (GAI) model trained on data including previous industrial design submissions from a plurality of users of an industrial design application, wherein the prompt comprises:
the metadata of the generic base design, and
a request to update the generic base design based on the previous industrial design submissions;
submit the prompt to the GAI model; and
receive, from the GAI model in response to the prompt, an updated base design comprising one or more differences from the generic base design,
wherein the differences are representative of previous selections made in the previous industrial design submissions from the plurality of users of the industrial design application.

12. The system of claim 11, wherein the determining that the trigger has been satisfied comprises one of:
receiving, from an administrator of the industrial design application, a request to update the generic base design,
determining that a pre-determined time-period has elapsed since a last update of the generic base design, and
determining that the generic base design has been selected for initial designs provided to users above a threshold number of times.

13. The system of claim 11, wherein the software instructions comprise further instructions that, upon execution by the one or more processors, cause the one or more processors to:
send to an administrator of the industrial design application, in response to receiving the updated generic base design, a request to review the updated base design; and
receive, from the administrator in response to the request, an approval of the updated base design.

14. The system of claim 13, wherein the software instructions comprise further instructions that, upon execution by the one or more processors, cause the one or more processors to:
replace, in response to receiving the approval, the generic base design with the updated base design.

15. The system of claim 11, wherein the software instructions comprise further instructions that, upon execution by the one or more processors, cause the one or more processors to:
receive a request from a user of the industrial design application for a design for an industrial automation project; and
send to the user, in response to the request for a design, an initial layout of the industrial automation project, the initial layout including the updated base design.

16. The system of claim 15, wherein the software instructions comprise further instructions that, upon execution by the one or more processors, cause the one or more processors to:
receive, from the user, a submission of a finalized layout of the industrial automation project, the finalized layout comprising one or more modifications of the initial layout; and
provide the finalized layout to the GAI model for updating learned common selections among users of the industrial design application.

17. The system of claim 11, wherein the software instructions comprise further instructions that, upon execution by the one or more processors, cause the one or more processors to:
provide the GAI model with static data during initial training, the static data comprising one or more of: industrial product literature, industry standard data, and safety requirements data.

18. The system of claim 11, wherein:
the generic base design comprises an initial option pack:
the initial option pack comprising a plurality of options selectable by users of an industrial design application to configure an aspect of the industrial unit;
the initial option pack further comprising a default selection of one of the plurality of options;
the updated generic base design comprises an updated option pack; and
the one or more differences comprise one or more differences between the initial option pack and the updated option pack.

19. The system of claim 18, wherein the one or more differences between the updated option pack and the initial option pack comprise one or more of:
a different default selection in the updated option pack compared to the initial option pack;
a new option of the plurality of options in the updated option pack compared to the initial option pack; and
a removed option of the plurality of options in the updated option pack compared to the initial option pack.

20. The system of claim 11, wherein the software instructions comprise further instructions that, upon execution by the one or more processors, cause the one or more processors to:
determine whether the generic base design is from an open design library or one of a plurality of company design libraries, wherein:
the open design library comprises a plurality of generic base designs available to all users of the industrial design application, and
each of the plurality of company design libraries comprises one or more generic base designs available only to users affiliated with a specific company; and
tailor the prompt depending on the determining whether the generic base design is from an open design library or one of the plurality of company design libraries.
